(19) United States
(12) Patent Application Publication
(10) Pub. No.: US 2025/0226025 A1
(43) Pub. Date: Jul. 10, 2025

(54) SEMICONDUCTOR MEMORY DEVICE

(71) Applicant: SAMSUNG ELECTRONICS CO., LTD., Suwon-si (KR)

(72) Inventors: KEONWOO PARK, Suwon-si (KR); Kyu-Chang Kang, Suwon-si (KR)

(73) Assignee: SAMSUNG ELECTRONICS CO., LTD., Suwon-si (KR)

(21) Appl. No.: 18/987,658

(22) Filed: Dec. 19, 2024

(30) Foreign Application Priority Data
Jan. 5, 2024 (KR) 10-2024-0001655

(51) Int. Cl. G11C 11/408; G11C 5/06; G11C 11/4091; H10B 12/00

(52) U.S. Cl. CPC G11C 11/4085; G11C 5/063; G11C 11/4091; H10B 12/50

(57) ABSTRACT

A semiconductor memory device, including: a first semiconductor structure including a first sub-memory cell array comprising a plurality of word lines, and a second semiconductor structure under the first semiconductor structure, wherein the second semiconductor structure includes: a first sub-word line driver configured to supply a word line driving voltage to a first end of a first word line from among the plurality of word lines, a second sub-word line driver configured to supply the word line driving voltage to a second end of the first word line, a third sub-word line driver configured to supply the word line driving voltage to a first end of a second word line from among the plurality of word lines, a fourth sub-word line driver configured to supply the word line driving voltage to a second end of the second word line.

### CROSS-REFERENCE TO RELATED APPLICATIONS

This application claims priority under 35 U.S.C. § 119 to Korean Patent Application No. 10-2024-0001655 filed on Jan. 4, 2024, in the Korean Intellectual Property Office, the disclosures of which are incorporated by reference herein in their entireties.

### BACKGROUND

### 1. Field

The present disclosure described relates to a semiconductor device, and more particularly, to a semiconductor memory device.

### 2. Description of Related Art

A semiconductor memory may be classified as a volatile memory, which may lose data stored therein when a power is turned off, such as a static random access memory (SRAM) or a dynamic random access memory (DRAM), or a nonvolatile memory device, which may retain data stored therein even when a power is turned off, such as a flash memory, a phase-change RAM (PRAM), a magnetic RAM (MRAM), a resistive RAM (RRAM), or a ferroelectric RAM (FRAM).

The DRAM device may include memory cells connected to a word line and a bit line. Through bit lines, the DRAM device may store data in memory cells or read data stored in memory cells. To drive word lines, the word lines may be divided into a plurality of sub-word lines, and each sub-word line may be driven using a sub-word line driver. To improve the degree of integration of the DRAM device, the thickness of the word line may become thinner, and the number of memory cells connected to the word line may be increased. However, this may increase a resistance of the word line, which may decrease the performance of operation of the DRAM device.

### SUMMARY

Provided is a semiconductor memory device with the improved performance of operation by providing an operating voltage to opposite ends of a word line.

Additional aspects will be set forth in part in the description which follows and, in part, will be apparent from the description, or may be learned by practice of the presented embodiments.

In accordance with an aspect of the disclosure, a semiconductor memory device includes: a first semiconductor structure including a first sub-memory cell array which includes a first plurality of word lines, a plurality of bit lines, and a plurality of memory cells, and a plurality of upper metal pads electrically connected to the first plurality of word lines and the plurality of bit lines; and a second semiconductor structure disposed under the first semiconductor structure, and including a plurality of sub-word line drivers, wherein the plurality of sub-word line drivers includes: a first sub-word line driver configured to supply a word line driving voltage to a first end of a first word line from among the first plurality of word lines, a second sub-word line driver configured to supply the word line driving voltage to a second end of the first word line, a third sub-word line driver configured to supply the word line driving voltage to a first end of a second word line from among the first plurality of word lines, a fourth sub-word line driver configured to supply the word line driving voltage to a second end of the second word line, and a plurality of lower metal pads electrically connected to the plurality of sub-word line drivers, and wherein each upper metal pad from among the plurality of upper metal pads is bonded to a corresponding lower metal pad from among the plurality of lower metal pads in a one-to-one correspondence.

In accordance with an aspect of the disclosure, a semiconductor memory device includes: a memory cell array structure on a first substrate and including a plurality of sub-memory cell arrays which include a plurality of word lines, a plurality of bit lines, and a plurality of memory cells; a core-peripheral circuit structure on a second substrate under the first substrate, wherein the core-peripheral circuit structure includes: a first sub-word line driver block configured to supply a word line driving voltage to first ends of first odd-numbered word lines from among a first plurality of word lines in a first sub-memory cell array from among the plurality of sub-memory cell arrays, a second sub-word line driver block configured to supply the word line driving voltage to second ends of the first odd-numbered word lines, a third sub-word line driver block configured to supply the word line driving voltage to first ends of first even-numbered word lines from among the first plurality of word lines, and a fourth sub-word line driver block configured to supply the word line driving voltage to second ends of the first even-numbered word lines; and a plurality of metal pad junctions electrically connecting the memory cell array structure with the core-peripheral circuit structure.

In accordance with an aspect of the disclosure, a semiconductor memory device includes a first substrate; a first sub-memory cell array on the first substrate and including a first plurality of word lines; a plurality of upper metal pads in a matrix array shape on the first sub-memory cell array; one or more first metal layers electrically connecting the plurality of upper metal pads with opposite ends of each word line of the first plurality of word lines; a second substrate on a lower side of the first substrate; a transistor layer on the second substrate and including a plurality of sub-word line drivers; a plurality of lower metal pads in the matrix array shape on an upper side of the transistor layer, wherein each lower metal pad from among the plurality of lower metal pads is bonded to a corresponding upper metal pad from among the plurality of upper metal pads; and one or more second metal layers electrically connecting the plurality of lower metal pads with the transistor layer, wherein each first sub-word line driver from among a plurality first sub-word line drivers included in the plurality of sub-word line drivers is electrically connected to a first metal contact formed at a first end of each odd-numbered word line from among a plurality of odd-numbered word lines included in the first plurality of word lines, wherein each second sub-word line driver from among a plurality of second sub-word line drivers included in the plurality of sub-word line drivers is electrically connected to a second metal contact formed at a second end of the each odd-numbered word line, wherein each third sub-word line driver from among a plurality of third sub-word line drivers included in the plurality of sub-word line drivers is electrically connected to a third metal contact formed at a first end of each even-numbered word line word line from among a plurality of even-numbered word lines included in the plurality of word lines, and wherein each fourth sub-word line driver from among a plurality of fourth sub-word line drivers included in the plurality of sub-word line drivers is electrically connected to a fourth metal contact formed at opposite second end of the each even-numbered word line.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram illustrating a semiconductor memory device according to an embodiment of the present disclosure;

FIG. 2 is a diagram illustrating a portion of a semiconductor memory device according to an embodiment of the present disclosure;

FIG. 3 is a diagram illustrating a plurality of word lines and a sub-word line driver included in a sub-memory cell array according to an embodiment of the present disclosure;

FIG. 4 is a circuit diagram illustrating a word line and a sub-word line driver according to an embodiment of the present disclosure;

FIG. 5 is a perspective view illustrating a sub-memory cell array of a semiconductor memory device according to an embodiment of the present disclosure;

FIG. 6 is a vertical cross-sectional view illustrating a semiconductor memory device according to an embodiment of the present disclosure;

FIG. 7 is a plan view illustrating placement of metal pad junctions in a sub-memory cell array according to an embodiment of the present disclosure;

FIG. 8 is a diagram illustrating vertical placement of a plurality of sub-memory cell arrays and a plurality of sub-word line drivers according to an embodiment of the present disclosure, when viewed in a cross-sectional view;

FIG. 9 is a diagram illustrating a portion of a memory cell array structure to an embodiment of the present disclosure;

FIG. 10 is a diagram illustrating a word line and a sub-word line driver according to an embodiment of the present disclosure;

FIG. 11 is a circuit diagram illustrating a configuration of sub-word line drivers according to an embodiment of the present disclosure;

FIG. 12 is a diagram illustrating another example of a memory cell array structure according to an embodiment of the present disclosure;

FIG. 13 is a diagram illustrating another example of a word line and a sub-word line driver according to an embodiment of the present disclosure;

FIG. 14 is a diagram illustrating a slope of a driving voltage for each location, according to an embodiment of the present disclosure;

FIG. 15A is a diagram illustrating placement of sub-memory cell arrays of a semiconductor memory device according to an embodiment of the present disclosure.

FIG. 15B is a diagram illustrating placement of core-peripheral circuits corresponding to sub-memory cell arrays of FIG. 15A, according to an embodiment of the present disclosure;

FIG. 16 is a diagram describing an integrated circuit device, according to an embodiment of the present disclosure;

FIG. 17 is a plan view illustrating the pad array PDA of an integrated circuit device of FIG. 16, according to an embodiment of the present disclosure;

FIG. 18A is a diagram illustrating a vertical cross section of an integrated circuit device taken along line A-A′ of FIG. 17, according to an embodiment of the present disclosure; and

FIG. 18B is a diagram illustrating a vertical cross section of an integrated circuit device taken along line B-B′ of FIG. 17 according to an embodiment of the present disclosure.

### DETAILED DESCRIPTION

Below, embodiments of the present disclosure are described in detail and

clearly to such an extent that an ordinary one in the art easily carries out the present disclosure.

As is traditional in the field, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the present scope. Further, the blocks, units and/or modules of the embodiments may be physically combined into more complex blocks, units and/or modules without departing from the present scope.

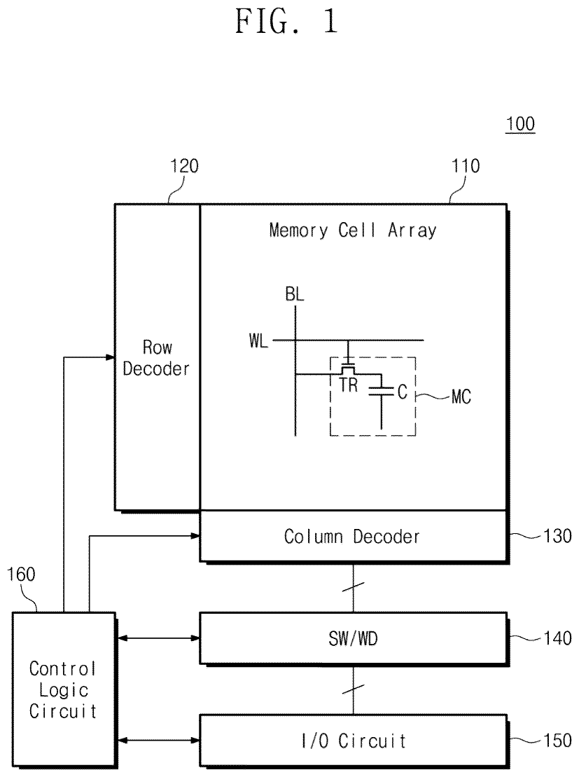

FIG. 1 is a block diagram illustrating a semiconductor memory device according to an embodiment of the present disclosure. Referring to FIG. 1, a semiconductor memory device 100 may include a memory cell array 110, a row decoder 120, a column decoder 130, a sense amplifier and write driver 140 (illustrated as “SW/WD”), an input/output circuit 150 (illustrated as “I/O Circuit”), and a control logic circuit 160. The semiconductor memory device 100 may be a dynamic random access memory (DRAM) device. However, embodiments are not limited thereto. For example, the semiconductor memory device 100 may include at least one of various memory devices such as an SRAM, an SDRAM, an MRAM, an FRAM an ReRAM, a PRAM, and a flash memory.

The memory cell array 110 may include memory cells MC connected to a plurality of word lines WL and a plurality of bit lines BL. Each of the memory cells MC may include a selection transistor TR and a storage capacitor C. The selection transistor TR may be connected between the storage capacitor C and the bit line BL and may operate based on a voltage of the word line WL. The storage capacitor C may be connected to the selection transistor TR and may store data depending on an operation of the selection transistor TR and a level of the bit line BL.

The row decoder 120 may be connected to the memory cell array 110 through the plurality of word lines WL. The row decoder 120 may decode a row address provided from an external device (e.g., a memory controller) and may control voltages of the word lines WL based on a result of the decoding.

The column decoder 130 may be connected to the memory cell array 110 through the plurality of bit lines BL. The column decoder 130 may decode a column address provided from the external device (e.g., a memory controller) and may control the plurality of bit lines BL based on a result of the decoding.

Through the plurality of bit lines BL, the sense amplifier and write driver 140 may read data stored in the memory cell array 110 or may write data in the memory cell array 110.

The input/output circuit 150 may transmit data to the external device (e.g., a memory controller) or may receive data from the external device. The input/output circuit 150 may provide the data received from the external device to the sense amplifier and write driver 140 or may provide the data received from the sense amplifier and write driver 140 to the external device.

The control logic circuit 160 may control various components included in the semiconductor memory device 100 based on a command or a control signal from the external device.

During the read operation or the write operation of the semiconductor memory device 100, a selection voltage, a word line enable voltage, or a high voltage (e.g., a voltage for turning on the selection transistor TR of the memory cell MC) may be applied to a word line WL included in the plurality of word lines WL.

According to embodiments, as the thickness of the word line WL on the memory cell array 110 is reduced, the number of memory cells MC connected to one word line WL may increase. Also, a structure in which a voltage is only applied to one end of the word line WL and an opposite end of the word line WL is floated may be adopted. In this case, as the electrical resistance of the word line WL increases, the slope of the voltage applied to the word line WL may become worse. This may mean that the performance of the semiconductor memory device 100 may deteriorate.

The semiconductor memory device 100 according to an embodiment of the present disclosure may improve the slope of the voltage applied to the word line WL by applying a driving voltage to opposite ends of the word line WL, and thus the performance of the semiconductor memory device 100 may be improved. Examples of the semiconductor memory device 100 according to an embodiment of the present disclosure are described in detail with reference to accompanying drawings.

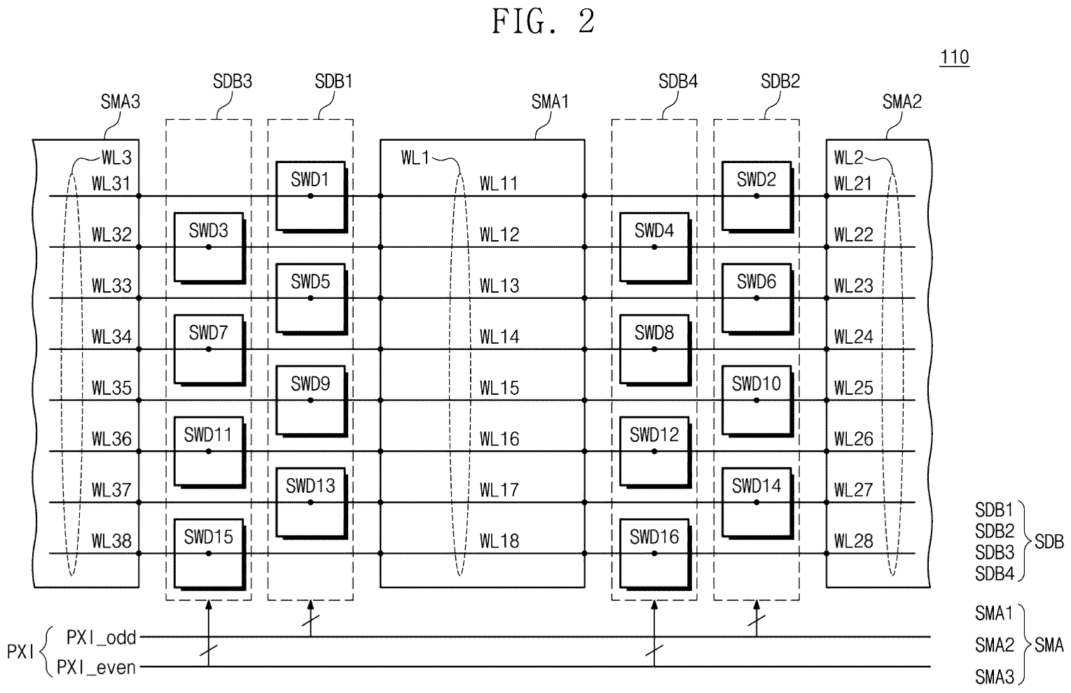

FIG. 2 is a diagram illustrating a portion of a semiconductor memory device according to an embodiment of the present disclosure. Referring to FIG. 2, the memory cell array 110 according to an embodiment of the present disclosure may include a plurality of sub-memory cell arrays SMA (e.g., first sub-memory cell array SMA1, second sub-memory cell array SMA2, and third sub-memory cell array SMA3) and a plurality of sub-word line drivers SWD (e.g., first sub-word line driver SWD1, second sub-word line driver SWD2, . . . , and sixteenth sub-word line driver SWD16.

In the present disclosure, for brevity of drawing and for convenience of description, components (e.g., bit lines and memory cells) which may be unnecessary to describe an embodiment of the present disclosure may be omitted in the drawings. However, embodiments are not limited thereto. In addition, although each sub-memory cell array is illustrated as including 8 or fewer word lines, embodiments are not limited thereto, and in some embodiments the number of word lines included in each sub-memory cell array may be increased and/or decreased.

The first sub-memory cell array SMA1 may include a first plurality of word lines WL1 (e.g., word line WL11, word line WL12, . . . , word line WL18). Opposite ends of each of the first plurality of word lines WL1 may be respectively connected to different sub-word line drivers SWD. For example, the first end of the word line WL11 may be connected to the first sub-word line driver SWD1, and the second end of the word line WL11 may be connected to the second sub-word line driver SWD2. Opposite ends of the word line WL12 may be respectively connected to the third sub-word line driver SWD3 and the fourth sub-word line driver SWD4.

The plurality of sub-word line drivers SWD may be grouped into a plurality of sub-word line driver blocks SDB (e.g., a first sub-word line driver block SDB1, a second sub-word line driver block SDB2, a third sub-word line driver block SDB3, and a fourth sub-word line driver block SDB4). For example, the first sub-word line driver block SDB1 may include the first sub-word line driver SWD1, a fifth sub-word line driver SWD5, a ninth sub-word line driver SWD9, and a thirteenth sub-word line driver SWD13. The second sub-word line driver block SDB2 may include the second sub-word line driver SWD2, a sixth sub-word line driver SWD6, a tenth sub-word line driver SWD10, and a fourteenth sub-word line driver SWD14. The third sub-word line driver block SDB3 may include a second sub-word line driver SWD3, a seventh sub-word line driver SWD7, an eleventh sub-word line driver SWD11, and a fifteenth sub-word line driver SWD15, and the fourth sub-word line driver block SDB4 may include a fourth sub-word line driver SWD4, an eighth sub-word line driver SWD8, a twelfth sub-word line driver SWD12, and the sixteenth sub-word line driver SWD16.

The plurality of sub-word line driver blocks SDB may operate based on a word line control signal PXI. According to an embodiment, the first sub-word line driver block SDB1 and the second sub-word line driver block SDB2 may drive the word lines WL11, WL13, WL15, and WL17, which may be odd-numbered word lines. The third sub-word line driver block SDB3 and the fourth sub-word line driver block SDB4 may drive the word lines WL12, WL14, WL16, and WL18, which may be even-numbered word lines. The first sub-word line driver block SDB1 and the second sub-word line driver block SDB2 may drive the odd-numbered word lines WL11, WL13, WL15, and WL17 based on the an odd-numbered word line control signal PXI_odd of the word line control signal PXI. The third sub-word line driver block SDB3 and the fourth sub-word line driver block SDB4 may drive the even-numbered word lines WL12, WL14, WL16, and WL18 based on the an even-numbered word line control signal PXI_even of the word line control signal PXI.

One side of the first sub-memory cell array SMA1 may be adjacent to the second sub-memory cell array SMA2, and an opposite side of the first sub-memory cell array SMA1, which faces away from the second sub-memory cell array SMA2, may be adjacent to the third sub-memory cell array SMA3. For example, the first sub-memory cell array SMA1 may be disposed between the second sub-memory cell array SMA2 and the third sub-memory cell array SMA3. The second sub-memory cell array SMA2 may include a plurality of word lines WL2 (e.g., word line WL21, word line WL22, word line WL23, . . . , word line WL28). The third sub-memory cell array SMA3 may include a plurality of word lines WL3 (e.g., word line WL31, word line WL32, . . . , word line WL38).

The second sub-word line driver SWD2 may be connected to the word line WL11 included in the first sub-memory cell array SMA1 and may be simultaneously connected to the word line WL21 included in the second sub-memory cell array SMA2. The first sub-word line driver SWD1 may be connected to the word line WL11 and may be simultaneously connected to the word line WL31 included in the third sub-memory cell array SMA3. The fourth sub-word line driver SWD4 may be connected to the word line WL12 included in the first sub-memory cell array SMA1 and may be simultaneously connected to the word line WL22 included in the second sub-memory cell array SMA2. The third sub-word line driver SWD3 may be connected to the word line WL12 and may be simultaneously connected to the word line WL32 included in the third sub-memory cell array SMA3.

The first sub-word line driver SWD1 and the second sub-word line driver SWD2 simultaneously drive opposite ends of the word line WL11. The first sub-word line driver SWD1 may further drive the word line WL31, and the second sub-word line driver SWD2 may further drive the word line WL21. The third sub-word line driver SWD3 and the fourth sub-word line driver SWD4 may simultaneously drive the word line WL12 at opposite locations; in this case, the third sub-word line driver SWD3 may further drive the word line WL32, and the fourth sub-word line driver SWD4 may further drive the word line WL22.

The first sub-word line driver block SDB1 and the second sub-word line driver block SDB2 may drive the odd-numbered word lines WL11, WL13, WL15, and WL17 included in the first sub-memory cell array SMA1. In addition, the first sub-word line driver block SDB1 may further drive the odd-numbered word lines WL31, WL33, WL35, and WL37 included in the third sub-memory cell array SMA3, and the second sub-word line driver block SDB2 may further drive the odd-numbered word lines WL21, WL23, WL25, and WL27 included in the second sub-memory cell array SMA2.

The third sub-word line driver block SDB3 and the fourth sub-word line driver block SDB4 may drive the even-numbered word lines WL12, WL14, WL16, and WL18 included in the first sub-memory cell array SMA1. In addition, the third sub-word line driver block SDB3 may further drive the even-numbered word lines WL32, WL34, WL36, and WL38 included in the third sub-memory cell array SMA3, and the fourth sub-word line driver block SDB4 may further drive the even-numbered word lines WL22, WL24, WL26, and WL28 included in the second sub-memory cell array SMA2.

Word lines which are included in different sub-memory cell arrays and connect sub-memory cell arrays may be simultaneously driven by the first to fourth sub-word line driver blocks SDB1 to SDB4. For example, the word lines WL11, WL21, and WL31 may be included in different sub-memory cell arrays, and the word lines WL11, WL21, and WL31 may connect the sub-memory cell arrays SMA1, SMA2, and SAM3. Accordingly, the word lines WL11, WL21, and WL31 may be simultaneously driven. Similarly, the word lines WL12, WL22, and WL32 may be simultaneously driven.

According to embodiments, one or more sub-word line driver blocks may be disposed on one side of the third sub-memory cell array SMA3, which faces away from the first and third sub-word line driver blocks SDB1 and SDB3. The sub-word line driver block disposed on one side facing away from the first and third sub-word line driver blocks SDB1 and SDB3 may drive the plurality of word lines WL3 of the third sub-memory cell array SMA3 simultaneously with the first and third sub-word line driver blocks SDB1 and SDB3.

According to an embodiment of the present disclosure, because a word line which is included in a sub-memory cell array and connects adjacent sub-memory cell arrays may be provided with a driving voltage from opposite ends of the word line, the slope of the driving voltage on the word line may be improved, and the performance of operation of the semiconductor memory device 100 may be improved.

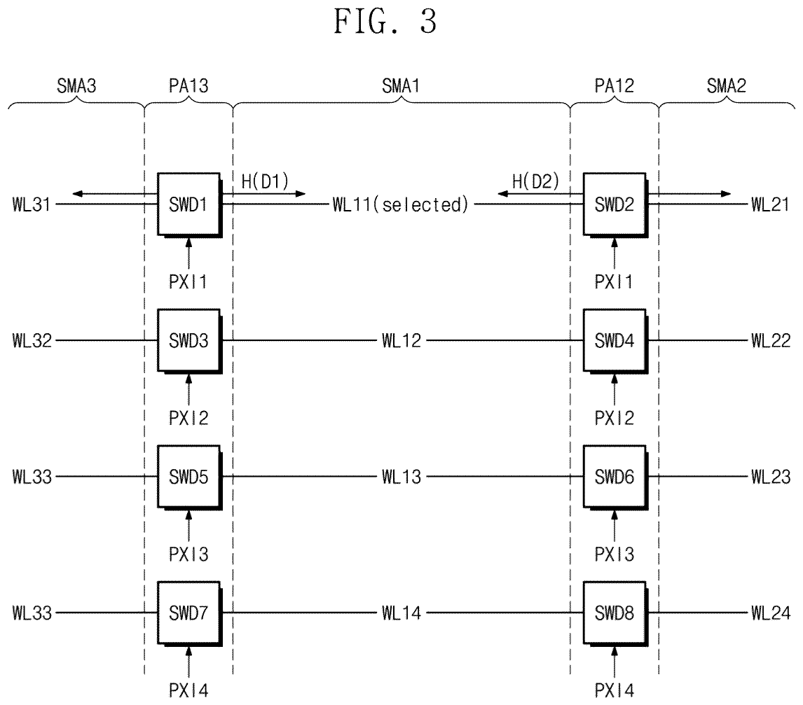

FIG. 3 is a diagram illustrating a plurality of word lines and a sub-word line driver included in a sub-memory cell array according to an embodiment of the present disclosure. Referring to FIG. 3, the first sub-word line driver SWD1 may supply the word line driving voltage to the word line WL11 in a first direction D1, and the second sub-word line driver SWD2 may supply the word line driving voltage to the word line WL11 in a second direction D2 facing toward the first direction D1.

A peripheral circuit region PA12 may be disposed between the first sub-memory cell array SMA1 and the second sub-memory cell array SMA2, and a peripheral circuit region PA13 may be disposed between the first sub-memory cell array SMA1 and the third sub-memory cell array SMA3. The plurality of sub-word line drivers SWD2, SWD4, SWD6, and SWD8 may be disposed in the peripheral circuit region PA12. The plurality of sub-word line drivers SWD1, SWD3, SWD5, and SWD7 may be disposed in the peripheral circuit region PA13.

The first sub-word line driver SWD1 and the second sub-word line driver SWD2 may control the word line WL11 based on a word line control signal PXI1. The third sub-word line driver SWD3 and the fourth sub-word line driver SWD4 may control the word line WL12 based on a word line control signal PXI2. The fifth sub-word line driver SWD5 and the sixth sub-word line driver SWD6 may control the word line WL13 based on a word line control signal PXI3, and the seventh sub-word line driver SWD7 and the eighth sub-word line driver SWD8 may control the word line WL14 based on a word line control signal PXI4.

The first sub-word line driver SWD1 may further control the word line WL31 based on the word line control signal PXI1, and the second sub-word line driver SWD2 may further control the word line WL21 based on the word line control signal PXI1. The third sub-word line driver SWD3 may further control the word line WL32 based on the word line control signal PXI2, and the fourth sub-word line driver SWD4 may further control the word line WL22 based on the word line control signal PXI2.

The word line control signal PXI1 and the word line control signal PXI3 of FIG. 3 may be included in the odd-numbered word line control signal PXI_odd of FIG. 2, and the word line control signal PXI2 and the word line control signal PXI4 of FIG. 3 may be included in the even-numbered word line control signal PXI_even of FIG. 2.

In an embodiment, when the word line WL11 is selected, each of the first sub-word line driver SWD1 and the second sub-word line driver SWD2 may apply a voltage having a first logic level (e.g., a high logic level) “H” generated by a voltage generator to the word line WL11, based on the word line control signal PXI generated by the row decoder 120 of FIG. 1. The first sub-word line driver SWD1 may be connected to one end of the word line WL11 and applies the voltage the high level “H” to the word line WL11 in a first direction (e.g., a rightward direction). The second sub-word line driver SWD2 may be connected to an opposite end of the word line WL11 and applies the voltage having the high logic level “H” to the word line WL11 in a second direction (e.g., a leftward direction) facing the first direction. In the word line WL11, because the voltages having the high logic level “H” are supplied from opposite ends of the word line WL11, the voltage slope of the word line WL11 may be improved. Because the slope of the voltage applied to the word line WL11 may be improved, the on-off timing of the selection transistor of the memory cell included in the first sub-memory cell array SMA1 may be improved, and the performance of operation of the semiconductor memory device 100 in the read operation or the write operation may be improved.

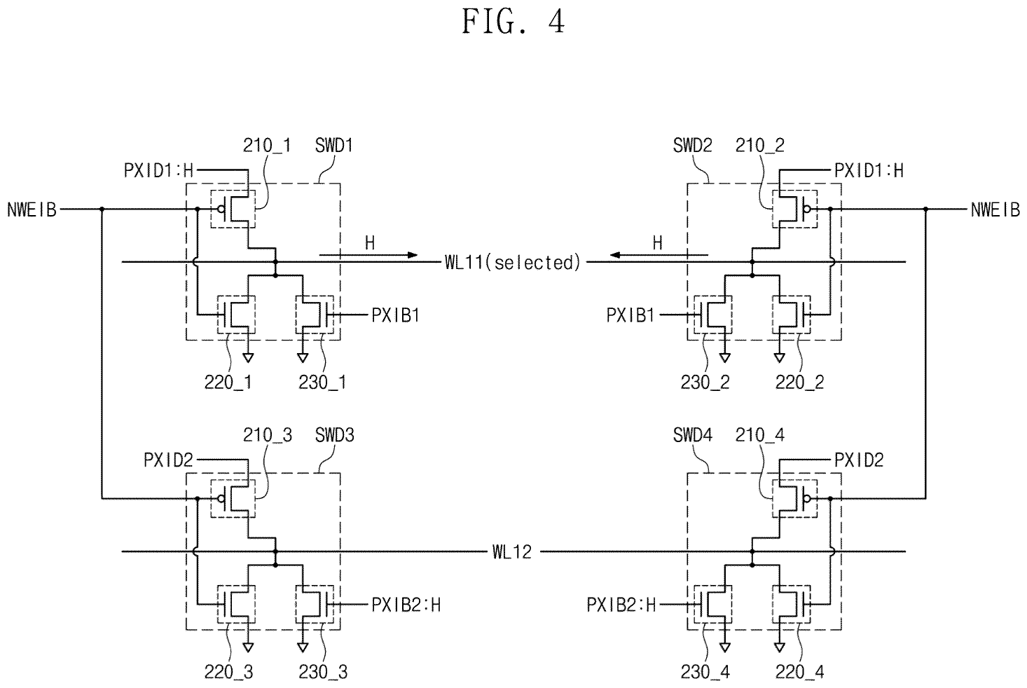

FIG. 4 is a circuit diagram illustrating a word line and a sub-word line driver according to an embodiment of the present disclosure. Referring to FIG. 4, the first sub-word line driver SWD1 configured to drive the word line WL11 may include a first transistor 210_1, a second transistor 220_1, and a third transistor 230_1. The first transistor 210_1 may be a PMOS transistor and may operate as a pull-up transistor. A word line enable signal NWEIB may be applied to a gate terminal of the first transistor 210_1, a word line driving signal PXID1 may be applied to a source terminal of the first transistor 210_1, and a drain terminal of the first transistor 210_1 may be connected to the word line WL11. The first transistor 210_1 may drive the word line WL11 corresponding to the word line driving signal PXID1 based on the word line enable signal NWEIB.

The second transistor 220_1 may be an NMOS transistor and may operate as a pull-down transistor. The word line enable signal NWEIB may be applied to a gate terminal of the second transistor 220_1, and a drain terminal and a source terminal of the second transistor 220_1 may be respectively connected to the drain terminal of the first transistor 210_1 and a ground terminal.

The third transistor 230_1 may be an NMOS transistor and may operate as a keeping transistor for keeping a corresponding word line at a ground level when the corresponding word line is not selected. An inverted word line driving signal PXIB1 may be applied to a gate terminal of the third transistor 230_1, and a drain terminal and a source terminal of the third transistor 230_1 may be respectively connected to the word line WL11 and the ground terminal.

The second sub-word line driver SWD2 configured to drive the word line WL11 on one side facing away from the first sub-word line driver SWD1 may include a first transistor 210_2, a second transistor 220_2, and a third transistor 230_2. The first to third transistors 210_2, 220_2, and 220_3 of the second sub-word line driver SWD2 may respectively correspond to the first to third transistors 210_1, 220_1, and 230_1 of the first sub-word line driver SWD1. The word line enable signal NWEIB may be applied to a gate terminal of the first transistor 210_2 of the second sub-word line driver SWD2, and the word line driving signal PXID1 may be applied to a source terminal of the first transistor 210_2.

The third sub-word line driver SWD3 may include a first transistor 210_3 corresponding to a pull-up transistor, a second transistor 220_3 corresponding to a pull-down transistor, and a third transistor 230_3 corresponding to a keeping transistor. The fourth sub-word line transistor SDW4 may include a first transistor 210_4 corresponding to a pull-up transistor, a second transistor 220_4 corresponding to a pull-down transistor, and a third transistor 230_4 corresponding to a keeping transistor. A word line driving signal PXID2 may be applied to the source terminal of each of the first transistors 210_3 and 210_4, and an inverted word line driving signal PXIB2 may be applied to the gate terminal of each of the third transistors 230_3 and 230_4.

The first to fourth sub-word line drivers SWD1, SWD2, SWD3, and SWD4 may be enabled (e.g., activated) by the word line enable signal NWEIB. The first transistors 210_1 and 210_2 of the first and second sub-word line drivers SWD1 and SWD2 may be turned on based on the word line enable signal NWEIB applied to the gate terminals of the first and second sub-word line drivers SWD1 and SWD2, and may apply the word line driving signal PXID1 having the high logic level “H” input to the source terminals of the first and second sub-word line drivers SWD1 and SWD2 to the selected word line WL11. In this case, the word line driving signal PXID1 having the high logic level “H” may be applied to the opposite ends of the word line WL11 by the first and second sub-word line drivers SWD1 and SWD2.

The third transistors 230_3 and 230_4 of the third and fourth sub-word line drivers SWD3 and SWD4 may be activated by the inverted word line driving signal PXIB2 and may keep the unselected word line WL12 at the ground level.

As shown in FIG. 4, the first transistors 210_1, 210_2, 210_3, and 210_3 may be implemented with a PMOS transistor but may be implemented with an NMOS transistor depending on a kind of a sub-word line driver. When an adjacent word line is selected, the third transistors 230_1, 230_2, 230_3, and 230_4 may perform a function of keeping unselected word lines at the ground level. When the third transistors 230_1, 230_2, 230_3, and 230_4 are removed, the second transistors 220_1, 220_2, 220_3, and 220_4 may assume the function of keeping unselected word lines at the ground level.

Although the example shown in FIG. 4 includes a CMOS-type sub-word line driver, embodiments are not limited thereto. For example, a sub-word line driver may include various types of sub-word line drivers including an NMOS-type sub-word line driver.

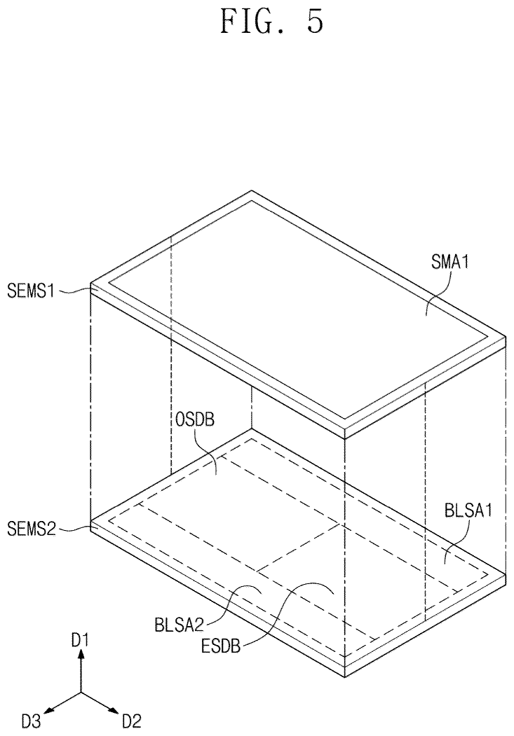

FIG. 5 is a perspective view illustrating a sub-memory cell array of a semiconductor memory device according to an embodiment of the present disclosure. Referring to FIG. 5, the semiconductor memory device 100 may include a first semiconductor structure SEMS1 and a second semiconductor structure SEMS2 disposed under (or on a lower side of) the first semiconductor structure SEMS1 (e.g., the first semiconductor structure SEMS1 may be in a direction D1 with respect to the second semiconductor structure SEMS1).

The first semiconductor structure SEMS1 may include a plurality of sub-memory cell arrays in which a plurality of word lines, a plurality of bit lines, and a plurality of memory cells are disposed. For example, the first semiconductor structure SEMS1 may include the first sub-memory cell array SMA1. The first semiconductor structure SEMS1 may include a plurality of upper metal pads which may be electrically connected to the plurality of word lines and the plurality of bit lines, respectively. The second semiconductor structure SEMS2 may include peripheral circuits. For example, the second semiconductor structure SEMS2 may include a first bit line sense amplifier circuit BLSA1, a second bit line sense amplifier circuit BLSA2, an odd-numbered sub-word line driver block OSDB, and an even-numbered sub-word line driver block ESDB. The second semiconductor structure SEMS2 may further include a plurality of lower metal pads which may be electrically connected to the first and second bit line sense amplifier circuits BLSA1 and BLSA2 and the odd-numbered and even-numbered sub-word line driver blocks OSDB and ESDB.

The first sub-memory cell array SMA1 may include a plurality of word lines and a plurality of bit lines. Some word lines of the plurality of word lines included in the first sub-memory cell array SMA1 may be referred to as “odd-numbered word lines”, and other word lines of the plurality of word lines included in the first sub-memory cell array SMA1 may be referred to as “even-numbered word lines”. The odd-numbered word lines and the even-numbered word lines may be alternatingly disposed.

The first and second bit line sense amplifier circuits BLSA1 and BLSA2 may be electrically connected to the bit lines included in the first sub-memory cell array SMA1. The first bit line sense amplifier circuit BLSA1 may be connected to some bit lines included in the first sub-memory cell array SMA1 to amplify a voltage difference of a selected bit line and a reference bit line. The second bit line sense amplifier circuit BLSA2 may be connected to other bit lines included in the first sub-memory cell array SMA1 to amplify a voltage difference of a selected bit line and a reference bit line. The first bit line sense amplifier circuit BLSA1 may be disposed in a first region disposed on a periphery from among regions under the first sub-memory cell array SMA1, and the second bit line sense amplifier circuit BLSA2 may be disposed in a second region disposed on the periphery and facing away from the first bit line sense amplifier circuit BLSA1 from among the regions under the first sub-memory cell array SMA1.

The odd-numbered sub-word line driver block OSDB and the even-numbered sub-word line driver block ESDB may be disposed between the first region and the second region. For example, the odd-numbered sub-word line driver block OSDB and the even-numbered sub-word line driver block ESDB may be disposed between the first bit line sense amplifier circuit BLSA1 and the second bit line sense amplifier circuit BLSA2. Each of the odd-numbered sub-word line driver block OSDB and the even-numbered sub-word line driver block ESDB may include a plurality of sub-word line drivers. Each of the sub-word line drivers included in the odd-numbered sub-word line driver block OSDB may be electrically connected to a corresponding odd-numbered word line of the odd-numbered word lines among the plurality of word lines included in the first sub-memory cell array SMA1 and may drive the odd-numbered corresponding word line. Each of the sub-word line drivers included in the even-numbered sub-word line driver block ESDB may be electrically connected to a corresponding even-numbered word line of the even-numbered word lines among the plurality of word lines included in the first sub-memory cell array SMA1 and may drive the corresponding even-numbered word line.

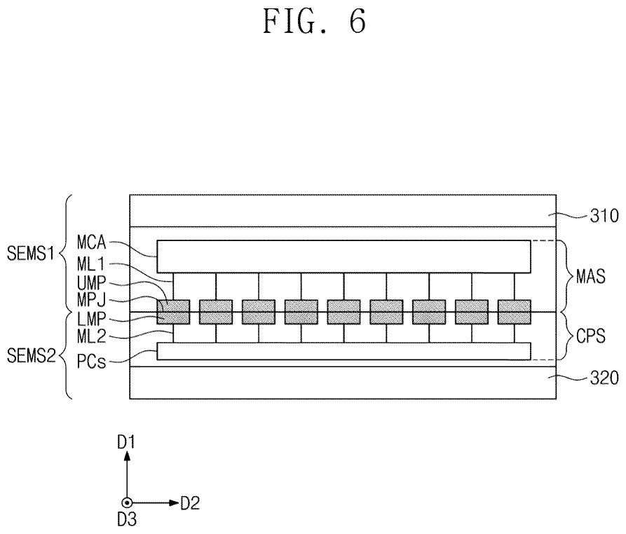

FIG. 6 is a vertical cross-sectional view illustrating a semiconductor memory device according to an embodiment of the present disclosure. Referring to FIG. 6, the first semiconductor structure SEMS1 may include a plurality of upper metal pads UMP which may be electrically connected to the plurality of word lines and the plurality of bit lines of the first sub-memory cell array SMA1. The second semiconductor structure SEMS2 may include a plurality of lower metal pads LMP which may be electrically connected to peripheral circuits PCs, respectively.

The first semiconductor structure SEMS1 may include a first substrate 310 and a memory cell array structure MAS formed on the first substrate 310. The memory cell array structure MAS may include a memory cell array MCA and a plurality of first metal lines ML1 configured to route signals of the plurality of word lines and the plurality of bit lines included in the memory cell array MCA. The memory cell array structure MAS may include the memory cell array 110 of FIG. 1. The memory cell array 110 may include a plurality of sub-memory cell arrays. Each of the first metal lines ML1 may be connected to one of bit lines and word lines of each of the sub-memory cell arrays to route a signal on a bit line or a word line to the outside of the memory cell array structure MAS.

The second semiconductor structure SEMS2 may include a second substrate 320 disposed on a lower side of the first substrate 310 and a core-peripheral circuit structure CPS formed on the second substrate 320. The core-peripheral circuit structure CPS may include the peripheral circuits PCs formed on the second substrate 320 and a plurality of second metal lines ML2 configured to route signals of the peripheral circuits PCs to the outside of the core-peripheral circuit structure CPS. As an example, the peripheral circuits PCs may include a plurality of sub-word line driver blocks and a plurality of bit line sense amplifier circuits. As another example, the peripheral circuits PC may include the row decoder 120, the column decoder 130, the sense amplifier and write driver 140, the input/output circuit 150, and the control logic circuit 160 of FIG. 1.

The upper metal pads UMP may be disposed at a lower end of the memory cell array structure MAS. The upper metal pads UMP may be electrically connected to the memory cell array MCA through the first metal lines ML1. The lower metal pads LMP may be disposed at an upper end of the core-peripheral circuit structure CPS. The lower metal pads LMP may be electrically connected to the peripheral circuits PC through the second metal lines ML2.

The lower and upper metal pads LMP and UMP may have the same size and the same arrangement. The lower and upper metal pads LMP and UMP may include, for example, copper (Cu), aluminum (Al), nickel (Ni), cobalt (Co), tungsten (W), titanium (Ti), tin (Sn), or an alloy thereof.

The semiconductor memory device 100 according to an embodiment of the present disclosure may have a bonding structure in which the first semiconductor structure SEMS1 and the second semiconductor structure SEMS2 are connected to each other through metal pads. The upper metal pads UMP of the first semiconductor structure SEMS1 and the lower metal pads LMP of the second semiconductor structure SEMS2 may be connected to each other electrically and physically by the bonding. For example, the lower metal pads LMP and the upper metal pads UMP may directly contact each other. The lower and upper metal pads LMP and UMP may be physically and electrically connected to each other through a plurality of metal pad junctions MPJ.

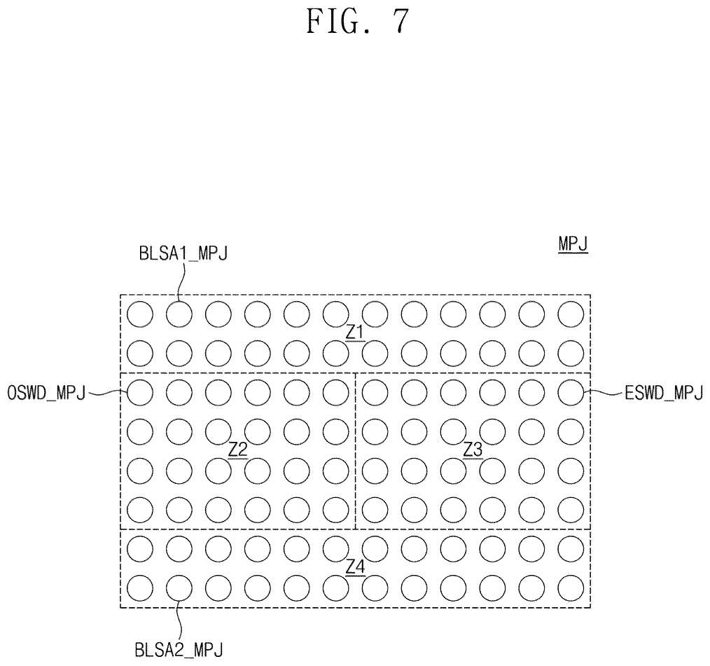

FIG. 7 is a plan view illustrating placement of metal pad junctions in a sub-memory cell array according to an embodiment of the present disclosure. Referring to FIG. 7, in the sub-memory cell array, the metal pad junctions MPJ may be classified into first to fourth zones (e.g., first zone Z1, second zone Z2, third zone Z3, and fourth zone Z4).

The first zone Z1 may correspond to one peripheral region of one sub-memory cell array. The fourth zone Z4 may correspond to a peripheral region of the sub-memory cell array, which faces away from the first zone Z1. The second zone Z2 and the third zone Z3 may correspond to a region between the first zone Z1 and the fourth zone Z4. For example, the second zone Z2 may correspond to a first half of the region between the first zone Z1 and the fourth zone Z4, and the third zone Z3 may correspond to a second half of the region between the first zone Z1 and the fourth zone Z4, which faces the first half of the region.

The first zone Z1 may include first bit line sense amplifier circuit metal pad junctions BLSA1_MPJ. The first bit line sense amplifier circuit metal pad junctions BLSA1_MPJ may electrically connect some bit lines disposed in the sub-memory cell array with a first bit line sense amplifier circuit.

The second zone Z2 may include odd-numbered sub-word line driver metal pad junctions OSWD_MPJ. The odd-numbered sub-word line driver metal pad junctions OSWD_MPJ may electrically connect odd-numbered word lines among word lines disposed in the sub-memory cell array and sub-word line drivers configured to drive the odd-numbered word lines.

The third zone Z3 may include even-numbered sub-word line driver metal pad junctions ESWD_MPJ. The even-numbered sub-word line driver metal pad junctions ESWD_MPJ may electrically connect even-numbered word lines among the word lines disposed in the sub-memory cell array and sub-word line drivers configured to drive the even-numbered word lines.

The fourth zone Z4 may include second bit line sense amplifier circuit metal pad junctions BLSA2_MPJ. The second bit line sense amplifier circuit metal pad junctions BLSA2_MPJ may electrically connect other bit lines disposed in the sub-memory cell array with a second bit line sense amplifier circuit.

Referring to FIGS. 5 and 7 together, the first bit line sense amplifier circuit BLSA1 of FIG. 5 may be electrically connected to some bit lines disposed in the first sub-memory cell array SMA1 through the first bit line sense amplifier circuit metal pad junctions BLSA1_MPJ of FIG. 7. The second bit line sense amplifier circuit BLSA2 of FIG. 5 may be electrically connected to other bit lines disposed in the first sub-memory cell array SMA1 through the second bit line sense amplifier circuit metal pad junctions BLSA2_MPJ of FIG. 7. The sub-word line drivers included in the odd-numbered sub-word line driver block OSDB of FIG. 5 may be electrically connected to the odd-numbered word lines among the word lines disposed in the first sub-memory cell array SMA1 through the odd-numbered sub-word line driver metal pad junctions OSWD_MPJ of FIG. 7, respectively. The sub-word line drivers included in the even-numbered sub-word line driver block ESDB of FIG. 5 may be electrically connected to the even-numbered word lines among the word lines disposed in the first sub-memory cell array SMA1 through the even-numbered sub-word line driver metal pad junctions ESWD_MPJ of FIG. 7, respectively.

According to embodiments, word line driving voltages which are applied through the odd-numbered sub-word line driver metal pad junctions OSWD_MPJ and the even-numbered sub-word line driver metal pad junctions ESWD_MPJ may also be transferred to another sub-memory cell array adjacent to the first sub-memory cell array SMA1 of FIG. 7.

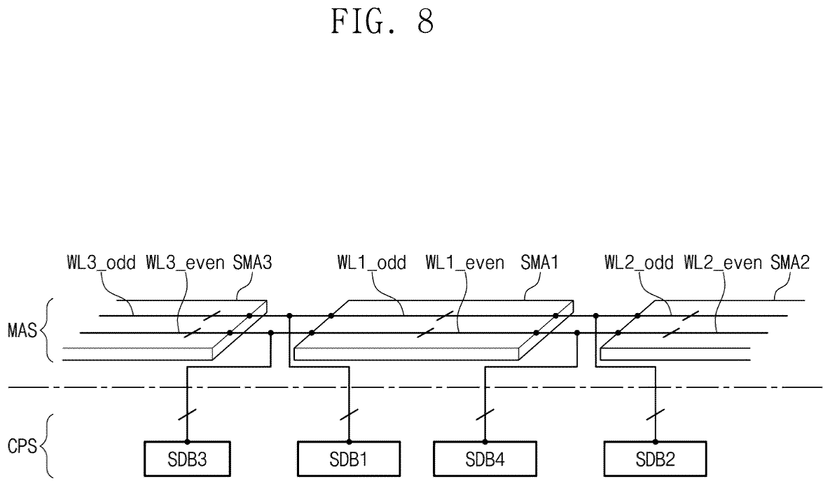

FIG. 8 is a diagram illustrating vertical placement of a plurality of sub-memory cell arrays and a plurality of sub-word line drivers according to an embodiment of the present disclosure, when viewed in a cross-sectional view. Referring to FIG. 8, the first to fourth sub-word line driver blocks SDB1, SDB2, SDB3, and SDB4 may drive the word lines included in the first sub-memory cell array SMA1.

The memory cell array structure MAS may include the plurality of sub-memory cell arrays SMA. The first sub-memory cell array SMA1 may include first odd-numbered word lines WL1_odd and first even-numbered word lines WL1_even. The second sub-memory cell array SMA2 may include second odd-numbered word lines WL2_odd and second even-numbered word lines WL2_even, and the third sub-memory cell array SMA3 may include third odd-numbered word lines WL3_odd and third even-numbered word lines WL3_even.

The core-peripheral circuit structure CPS may include the plurality of sub-word line driver blocks SDB. The sub-word line drivers included in the first sub-word line driver block SDB1 may drive the first odd-numbered word lines WL1_odd included in the first sub-memory cell array SMA1. The sub-word line drivers included in the first sub-word line driver block SDB1 may further drive the third odd-numbered word lines WL3_odd included in the third sub-memory cell array SMA3. The sub-word line drivers included in the second sub-word line driver block SDB2 may drive the first odd-numbered word lines WL1_odd included in the first sub-memory cell array SMA1. The sub-word line drivers included in the second sub-word line driver block SDB2 may further drive the second odd-numbered word lines WL2_odd included in the second sub-memory cell array SMA2. The sub-word line drivers included in the third sub-word line driver block SDB3 may drive the first even-numbered word lines WL1_even included in the first sub-memory cell array SMA1. The sub-word line drivers included in the third sub-word line driver block SDB3 may further drive the third even-numbered word lines WL3_even included in the third sub-memory cell array SMA3. The sub-word line drivers included in the fourth sub-word line driver block SDB4 may drive the first even-numbered word lines WL1_even included in the first sub-memory cell array SMA1. The sub-word line drivers included in the fourth sub-word line driver block SDB4 may further drive the second even-numbered word lines WL2_even included in the second sub-memory cell array SMA2.

The first odd-numbered word lines WL1_odd included in the first sub-memory cell array SMA1 may be driven by the sub-word line drivers included in the first sub-word line driver block SDB1 and the second sub-word line driver block SDB2. In this case, when the first odd-numbered word line WL1_odd is driven, the word line driving voltages may be respectively applied from opposite ends of the first odd-numbered word line WL1_odd. In this case, the sub-word line drivers included in the first sub-word line driver block SDB1 may apply the word line driving voltages in a first direction (e.g., a rightward direction) when the first odd-numbered word lines WL1_odd are driven, and the sub-word line drivers included in the second sub-word line driver block SDB2 may apply the word line driving voltages in a second direction (e.g., a leftward direction) facing away from the first direction when the first odd-numbered word lines WL1_odd are driven.

The first even-numbered word lines WL1_even included in the first sub-memory cell array SMA1 may be driven by the sub-word line drivers included in the third sub-word line driver block SDB3 and the fourth sub-word line driver block SDB4. In this case, when the first even-numbered word line WL1_even is driven, the word line driving voltages are respectively applied from opposite ends of the first even-numbered word line WL1_even. In this case, the sub-word line drivers included in the third sub-word line driver block SDB3 may apply the word line driving voltages in the first direction when the first even-numbered word lines WL1_even are driven, and the sub-word line drivers included in the fourth sub-word line driver block SDB4 may apply the word line driving voltages in the second direction facing the first direction when the first even-numbered word lines WL1_even are driven.

Because each of the first odd-numbered word lines WL1_odd and the first even-numbered word line WL1_even included in the first sub-memory cell array SMA1 may be supplied with the word line driving voltages from opposite ends, the slope of the voltage applied to each word line may be improved. Accordingly, the timing to drive each word line may be improved. This may mean that the performance of the semiconductor memory device 100 is improved.

According to embodiments, the sub-word line drivers included in the first sub-word line driver block SDB1 may be disposed on one side of a region under the first sub-memory cell array SMA1. The sub-word line drivers included in the second sub-word line driver block SDB2 may be disposed in a region under the second sub-memory cell array SMA2 adjacent to the first sub-memory cell array SMA1. The sub-word line drivers included in the third sub-word line driver block SDB3 may be disposed in a region under the third sub-memory cell array SMA3, which is adjacent to the first sub-memory cell array SMA1 and faces away from the second sub-memory cell array SMA2. The sub-word line drivers included in the fourth sub-word line driver block SDB4 may be disposed in a region under the first sub-memory cell array SMA1. In this case, the sub-word line drivers included in the fourth sub-word line driver block SDB4 may be disposed on an opposite side of the first sub-word line driver block SDB1.

The first sub-word line driver block SDB1 and the second sub-word line driver block SDB2 may correspond to the odd-numbered sub-word line driver block OSDB of FIG. 6, and the third sub-word line driver block SDB3 and the fourth sub-word line driver block SDB4 may correspond to the even-numbered sub-word line driver block ESDB.

Because the plurality of sub-word line driver blocks SDB may be disposed under the plurality of sub-memory cell arrays SMA, the planar size of the memory cell array may be reduced. Also, because the driving voltages may be respectively supplied from opposite ends of each word line, the performance of operation of the semiconductor memory device 100 may be improved.

In the example shown in FIG. 8, the first, second, and third odd-numbered word lines WL1_odd, WL2_odd, and WL3_odd and the first, second, and third even-numbered word lines WL1_even, WL2_even, and WL3_even are illustrated as being separated, embodiments are not limited thereto. For example, in some embodiments respective word lines included in the first, second, and third odd-numbered word lines WL1_odd, WL2_odd, and WL3_odd and respective word lines included in the first, second, and third even-numbered word lines WL1_even, WL2_even, and WL3_even may be alternatingly disposed on a plane.

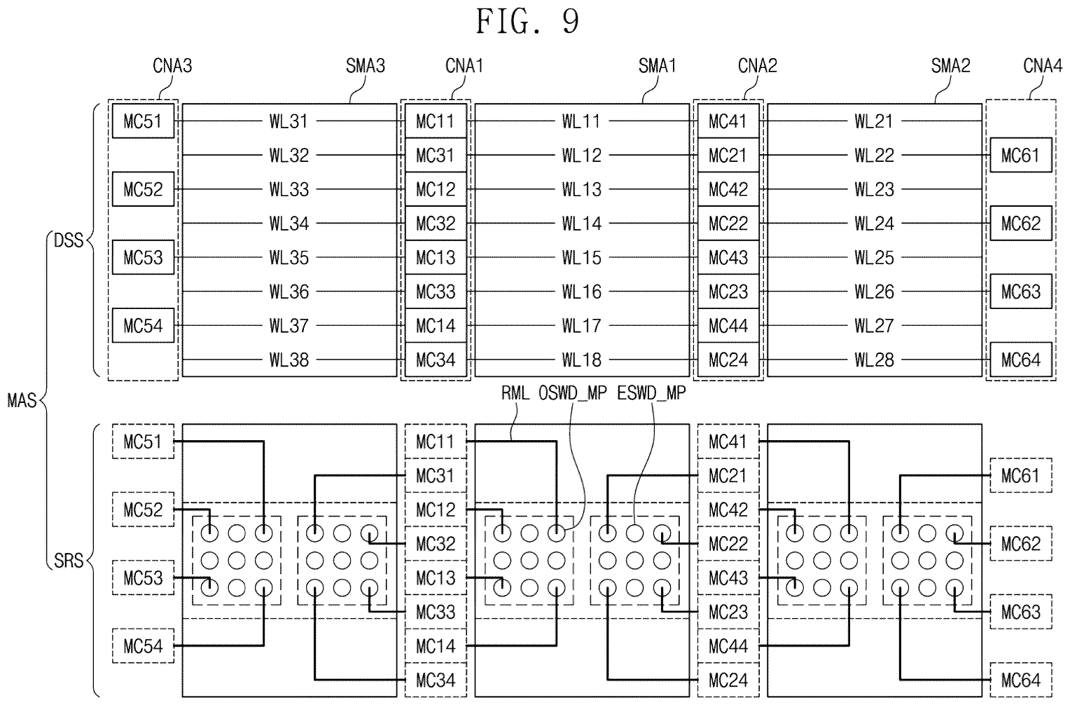

FIG. 9 is a diagram illustrating a portion of a memory cell array structure to an embodiment of the present disclosure. Referring to FIG. 9, the memory cell array structure MAS may include a data storage structure DSS and a signal routing structure SRS.

The data storage structure DSS may include a plurality of memory cells storing data and word lines and bit lines for accessing the plurality of memory cells. However, as in the above description, the memory cells and the bit lines may be omitted for convenience of description. The data storage structure DSS may include the plurality of sub-memory cell arrays SMA. Each of the plurality of sub-memory cell arrays SMA may include a plurality of word lines. The first sub-memory cell array SMA1 may include the first plurality of word lines WL1, the second sub-memory cell array SMA2 may include the second plurality of word lines WL2, and the third sub-memory cell array SMA3 may include the third plurality of word lines WL3. The second sub-memory cell array SMA2 may be disposed adjacent to one side of the first sub-memory cell array SMA1, and the third sub-memory cell array SMA3 may be disposed adjacent to an opposite side of the first sub-memory cell array SMA1, which faces away from the second sub-memory cell array SMA2.

The first to third pluralities of word lines WL1, WL2, and WL3 included in the data storage structure DSS may be connected to at least one metal contact among a plurality of metal contacts MC11, MC12, . . . , MC64. For example, one end of the word line WL11 may be connected to the metal contact MC11, and an opposite end of the word line WL11 may be connected to the metal contact MC41. The word line WL12 may be connected to the metal contact MC31 and the metal contact MC21. The word line WL21 may be connected to the metal contact MC41. The word line WL22 may be connected to the metal contact MC21 and the metal contact MC61. The word line WL31 may be connected to the metal contact MC51 and the metal contact MC11. The word line WL32 may be connected to the metal contact MC31.

The plurality of metal contacts MC11 to MC64 may be formed in connection areas CNA1, CNA2, etc. For example, the metal contacts MC11, MC31, MC12, MC32, MC13, MC33, MC14, and MC34 may be formed in the first connection area CNA1 between the first sub-memory cell array SMA1 and the third sub-memory cell array SMA3. The metal contacts MC41, MC21, MC42, MC22, MC43, MC23, MC44, and MC24 may be formed in the second connection area CNA2 between the first sub-memory cell array SMA1 and the second sub-memory cell array SMA2. The metal contacts MC51, MC52, MC53, and MC54 may be formed in the third connection area CNA3. The metal contacts MC61, MC62, MC63, and MC64 may be formed in the fourth connection area CNA4.

The signal routing structure SRS may include odd-numbered sub-word line driver metal pads OSWD_MP, even-numbered sub-word line driver metal pads ESWD_MP, and a plurality of routing metal lines RML. The odd-numbered sub-word line driver metal pads OSWD_MP may correspond to some upper metal pads UMP of FIG. 6. The odd-numbered sub-word line driver metal pads OSWD_MP may be electrically connected to the sub-word line drivers included in the odd-numbered sub-word line driver block OSDB of FIG. 5. The odd-numbered sub-word line driver metal pads OSWD_MP may correspond to the odd-numbered sub-word line driver metal pad junctions OSWD_MPJ of FIG. 7. The even-numbered sub-word line driver metal pads ESWD_MP may correspond to other upper metal pads UMP of FIG. 6. The even-numbered sub-word line driver metal pads ESWD_MP may be electrically connected to the sub-word line drivers included in the even-numbered sub-word line driver block ESDB of FIG. 5. The even-numbered sub-word line driver metal pads ESWD_MP may correspond to the even-numbered sub-word line driver metal pad junctions ESWD_MPJ of FIG. 7.

Each of the routing metal lines RML may electrically connect the corresponding metal pad and the corresponding metal contact. For example, one of the routing metal lines RML may connect one of the odd-numbered sub-word line driver metal pads OSWD_MP and the metal contact MC11. Another of the routing metal lines RML may connect another of the odd-numbered sub-word line driver metal pads OSWD_MP and the metal contact MC12. Yet another of the routing metal lines RML may connect one of the even-numbered sub-word line driver metal pads ESWD_MP and the metal contact MC21. And yet another of the routing metal lines RML may connect another of the even-numbered sub-word line driver metal pads ESWD_MP and the metal contact MC22.

For example, the sub-word line drivers included in the odd-numbered sub-word line driver block disposed under the first sub-memory cell array SMA1 may be electrically connected to the metal contacts MC11, MC12, MC13, and MC14 through the routing metal lines RML. The sub-word line drivers included in the even-numbered sub-word line driver block disposed under the first sub-memory cell array SMA1 may be electrically connected to the metal contacts MC21, MC22, MC23, and MC24 through the routing metal lines RML. The sub-word line drivers included in the odd-numbered sub-word line driver block disposed under the second sub-memory cell array SMA2 may be electrically connected to the metal contacts MC41, MC42, MC43, and MC44 through the routing metal lines RML. The sub-word line drivers included in the even-numbered sub-word line driver block disposed under the second sub-memory cell array SMA2 may be electrically connected to the metal contacts MC61, MC62, MC63, and MC64 through the routing metal lines RML. The sub-word line drivers included in the even-numbered sub-word line driver block disposed under the third sub-memory cell array SMA3 may be electrically connected to the metal contacts MC51, MC52, MC53, and MC54 through the routing metal lines RML. The sub-word line drivers included in the even-numbered sub-word line driver block disposed under the third sub-memory cell array SMA3 may be electrically connected to the metal contacts MC31, MC32, MC33, and MC34 through the routing metal lines RML. According to embodiments, the routing metal lines RML may be formed in one or more metal layers included in the memory cell array structure MAS. The routing metal lines RML may correspond to the first metal lines ML1 of FIG. 6.

When the sub-word line driver corresponding to the word line WL11 from among the sub-word line drivers disposed under the first sub-memory cell array SMA1 applies the word line driving voltage, the word line driving voltage may be applied to the word line WL11 through the metal contact MC11. Also, the sub-word line driver corresponding to the word line WL11 from among the sub-word line drivers disposed under the second sub-memory cell array SMA2 may simultaneously apply the word line driving voltage. In this case, the driving voltage may be applied to the word line WL11 through the metal contact MC41. As a result, the word line WL11 may be supplied with the word line driving voltages from opposite ends thereof. Accordingly, the slope of the driving voltage may be improved, and the performance of operation of the semiconductor memory device 100 may be improved.

Because the plurality of sub-word line drivers may be not disposed between the plurality of sub-memory cell arrays SMA, but instead may be disposed under the plurality of sub-memory cell arrays SMA, the planar size of the memory cell array may be reduced.

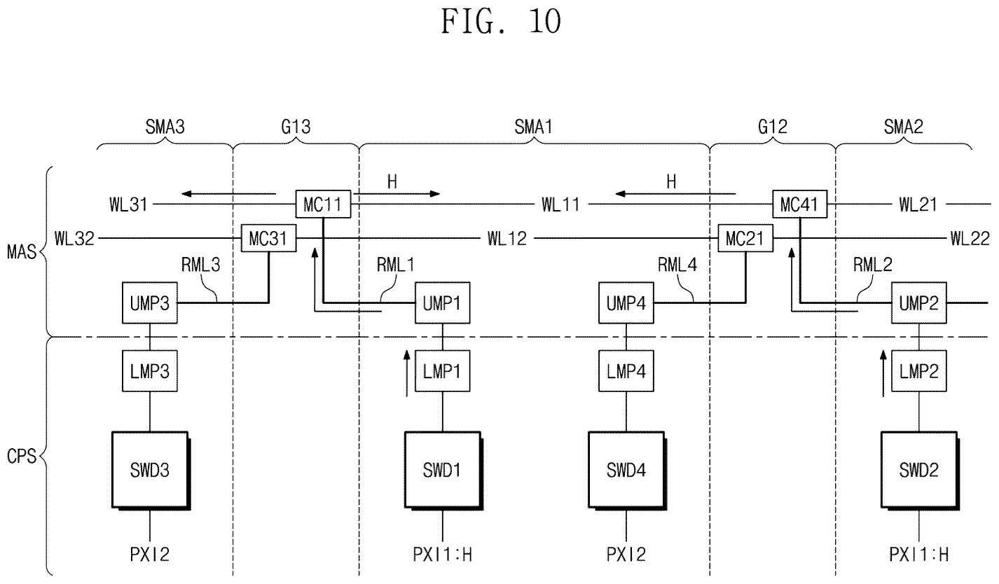

FIG. 10 is a diagram illustrating a word line and a sub-word line driver according to an embodiment of the present disclosure. Referring to FIG. 10, the first sub-word line driver SWD1 may supply the word line driving voltage to the word line WL11 in a first direction, and the second sub-word line driver SWD2 may supply the word line driving voltage to the word line WL11 in a second direction facing the first direction.

A gap region G12 may be disposed between the first sub-memory cell array SMA1 and the second sub-memory cell array SMA2, and a gap region G13 may be disposed between the first sub-memory cell array SMA1 and the third sub-memory cell array SMA3. The metal contact MC41 and the metal contact MC21 may be formed in the gap region G12, and the metal contact MC11 and the metal contact MC31 may be formed in the gap region G13. Each of the gap regions G12 and G13 where the metal contacts MC11, MC21, MC31, and MC41 are formed may correspond to the connection area described above.

The metal contact MC11 may contact a first end of the word line WL11 and a first end of the word line WL31. The metal contact MC21 may contact a first end of the word line WL12 and a first end of the word line WL22. The metal contact MC31 may contact a second end of the word line WL12 and a first end of the word line WL32. The metal contact MC41 may contact a second end of the word line WL11 a first end of the word line WL21.

The first sub-word line driver SWD1 and the second sub-word line driver SWD2 may control the word line WL11 based on the word line control signal PXI1. The third sub-word line driver SWD3 and the fourth sub-word line driver SWD4 may control the word line WL12 based on the word line control signal PXI2.

The first sub-word line driver SWD1 may output the word line driving voltage having a first logic level (e.g., the high logic level “H”) based on the word line control signal PXI1. The word line driving voltage output through the first sub-word line driver SWD1 may be transferred to a lower metal pad LMP1. The output word line driving voltage may be transferred to an upper metal pad UMP1 through the metal pad junction. The word line driving voltage may be transferred to the metal contact MC11 through a routing metal line RML1 formed in one or more metal layers. The output word line driving voltage may be applied to the word line WL11 from the metal contact MC11. In addition, the output word line driving voltage may also be applied to the word line WL31 from the metal contact MC11.

The second sub-word line driver SWD2 may output the word line driving voltage having the high logic level “H” to the word line WL11 based on the word line control signal PXI1 being the same control signal as the first sub-word line driver SWD1. The word line driving voltage output through the second sub-word line driver SWD2 may be applied to the word line WL11 through a lower metal pad LMP2, the metal pad junction, an upper metal pad UMP2, a routing metal line RML2, and the metal contact MC41. In addition, the output word line driving voltage may also be applied to the word line WL21.

The output voltage of the third sub-word line driver SWD3 may be applied to the word line WL12 and the word line WL32 through a lower metal pad LMP3, the metal pad junction, an upper metal pad UMP3, a routing metal line RML3, and the metal contact MC31. The output voltage of the fourth sub-word line driver SWD4 may be applied to the word line WL12 and the word line WL22 through a lower metal pad LMP4, the metal pad junction, an upper metal pad UMP4, a routing metal line RML4, and the metal contact MC21.

In the semiconductor memory device 100 according to an embodiment of the present disclosure, because the word line driving voltages may be applied to the opposite ends of the word line WL11 through the metal contact MC11 and the metal contact MC41, the slope of the word line driving voltage may be improved compared to the case where the word line driving voltage is only applied to one end of the word line WL11.

According to embodiments, the plurality of sub-word line drivers SWD may be disposed in the core-peripheral circuit structure CPS under (or on the lower side of) the sub-memory cell arrays SMA1, SMA2, etc., not between the sub-memory cell arrays SMA1, SMA2, etc. Accordingly, the horizontal size of the semiconductor memory device 100 according to an embodiment of the present disclosure may be smaller than a comparative example in which the plurality of sub-word line drivers SWD may be disposed in the same plane as the sub-memory cell arrays SMA1, SMA2, etc.

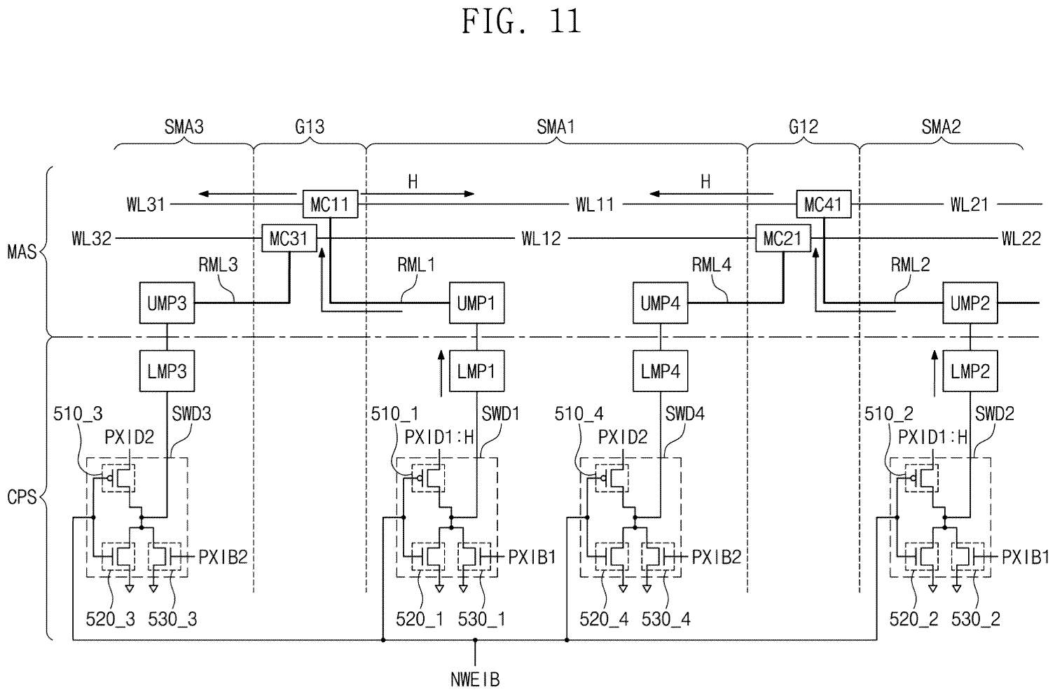

FIG. 11 is a circuit diagram illustrating a configuration of sub-word line drivers according to an embodiment of the present disclosure. Referring to FIG. 11, the first sub-word line driver SWD1 configured to drive the word line WL11 and the word line WL31 may include a first transistor 510_1, a second transistor 520_1, and a third transistor 530_1. The first transistor 510_1 may be a PMOS transistor and may operate as a pull-up transistor. The word line enable signal NWEIB may be applied to a gate terminal of the first transistor 510_1, the word line driving signal PXID1 may be applied to a source terminal of the first transistor 510_1, and a drain terminal of the first transistor 510_1 is connected to the lower metal pad LMP1. The first transistor 510_1 may output the word line driving signal PXID1 to the lower metal pad LMP1 based on the word line enable signal NWEIB.

The second transistor 520_1 may be an NMOS transistor and may operate as a pull-down transistor. The word line enable signal NWEIB may be applied to a gate terminal of the second transistor 520_1, and a drain terminal and a source terminal of the second transistor 520_1 may be respectively connected to the drain terminal of the first transistor 510_1 (or the lower metal pad LMP1) and the ground terminal.

The third transistor 530_1 may be an NMOS transistor and may operate as a keeping transistor for keeping the corresponding word lines WL11 and WL31 at the ground level when the corresponding word lines WL11 and WL31 are not selected. The inverted word line driving signal PXIB1 may be applied to a gate terminal of the third transistor 530_1, and a drain terminal and a source terminal of the third transistor 530_1 may be respectively connected to the drain terminal of the first transistor 510_1 (or the lower metal pad LMP1) and the ground terminal.

The first transistor 510_1, the second transistor 520_1, and the third transistor 530_1 of the first sub-word line driver SWD1 may be formed in the core-peripheral circuit structure CPS. For example, the first transistor 510_1, the second transistor 520_1, and the third transistor 530_1 may be formed in a transistor layer of the core-peripheral circuit structure CPS. The first transistor 510_1, the second transistor 520_1, and the third transistor 530_1 may be formed under (or on the lower side of) the first sub-memory cell array SMA1.

The second sub-word line driver SWD2 configured to drive the word line WL11 and the word line WL21 may include a first transistor 510_2, a second transistor 520_2, and a third transistor 530_2. The first transistor 510_2 may be a PMOS transistor and may operate as a pull-up transistor. The first transistor 510_2 may output the word line driving signal PXID1 to the lower metal pad LMP2 based on the word line enable signal NWEIB. The second transistor 520_2 may be an NMOS transistor and may operate as a pull-down transistor. The third transistor 530_2 may be an NMOS transistor and may operate as a keeping transistor for keeping the corresponding word lines WL11 and WL21 at the ground level when the corresponding word lines WL11 and WL21 are not selected.

The first transistor 510_2, the second transistor 520_2, and the third transistor 530_2 of the second sub-word line driver SWD2 may be formed in the core-peripheral circuit structure CPS. For example, the first transistor 510_2, the second transistor 520_2, and the third transistor 530_2 may be formed in the transistor layer of the core-peripheral circuit structure CPS. The first transistor 510_2, the second transistor 520_2, and the third transistor 530_2 may be formed under (or on the lower side of) the second sub-memory cell array SMA2.

The third sub-word line driver SWD3 may include a first transistor 510_3, a second transistor 520_3, and a third transistor 530_3. The fourth sub-word line driver SWD4 may include a first transistor 510_4, a second transistor 520_4, and a third transistor 530_4. Each of the first transistors 510_3 and 510_4 may output the word line driving signal PXID2 to each of the lower metal pads LMP3 and LMP4 based on the word line enable signal NWEIB. Each of the second transistors 520_3 and 520_4 may be an NMOS transistor and may operate as a pull-down transistor. Each of the third transistors 530_3 and 530_4 may be an NMOS transistor and may operate as a keeping transistor for keeping the corresponding word lines WL12 and WL22 or the corresponding word lines WL12 and WL32 at the ground level when the corresponding word lines WL12 and WL22 or the corresponding word lines WL12 and WL32 are not selected.

The first transistor 510_3, the second transistor 520_3, and the third transistor 530_3 of the third sub-word line driver SWD3 may be formed in the core-peripheral circuit structure CPS. For example, the first transistor 510_3, the second transistor 520_3, and the third transistor 530_3 may be formed in the transistor layer of the core-peripheral circuit structure CPS. The first transistor 510_3, the second transistor 520_3, and the third transistor 530_3 may be formed under (or on the lower side of) the third sub-memory cell array SMA3.

The first transistor 510_4, the second transistor 520_4, and the third transistor 530_4 of the fourth sub-word line driver SWD4 may be formed in the core-peripheral circuit structure CPS. For example, the first transistor 510_4, the second transistor 520_4, and the third transistor 530_4 may be formed in the transistor layer of the core-peripheral circuit structure CPS. The first transistor 510_4, the second transistor 520_4, and the third transistor 530_4 may be formed under (or on the lower side of) the first sub-memory cell array SMA1.

When the word line WL11 is driven, the word line driving signal PXID1 having the high logic level “H” input through the first transistor 510_1 of the first sub-word line driver SWD1 may be applied to the word line WL11 through the lower metal pad LMP1, the upper metal pad UMP1, the routing metal line RML1, and the metal contact MC11. The word line driving signal PXID1 having the high logic level “H” input through the first transistor 510_2 of the second sub-word line driver SWD2 may be applied to the word line WL11 through the lower metal pad LMP2, the upper metal pad UMP2, the routing metal line RML2, and the metal contact MC41. For example, because the word line driving signals PXID1 having the high logic level “H” may be applied to the word line WL11 from the metal contact MC11 and the metal contact MC41, the slope of the word line driving voltage may be improved, and the performance of the semiconductor memory device 100 may be improved. Also, the plurality of transistors 510_1, 520_1, . . . , 530_4 included in the plurality of sub-word line drivers SWD1, SWD2, SWD3, and SWD4 may be disposed in the transistor layer of the core-peripheral circuit structure CPS under the memory cell array structure MAS. Accordingly, the horizontal area of the semiconductor memory device 100 may be reduced.

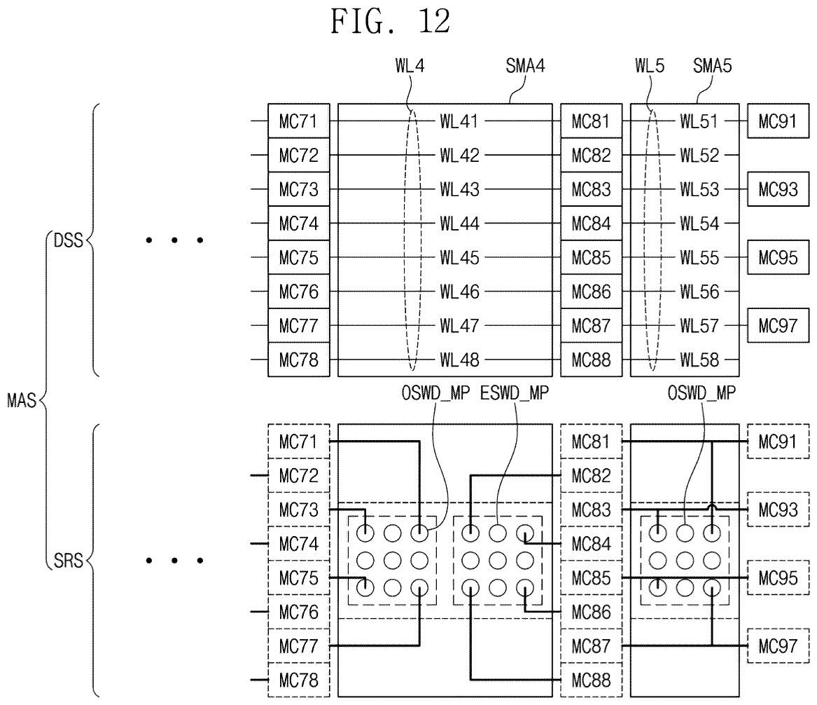

FIG. 12 is a diagram illustrating another example of a memory cell array structure according to an embodiment of the present disclosure. Referring to FIG. 12, the memory cell array structure MAS may include the data storage structure DSS and the signal routing structure SRS. The data storage structure DSS may include a fourth sub-memory cell array SMA4 and a fifth sub-memory cell array SMA5.

The fourth sub-memory cell array SMA4 may include a plurality of word lines WL4 (e.g., world lines WL41 to WL48), and the fifth sub-memory cell array SMA5 may include a plurality of word lines WL5 (e.g., word lines WL51 to WL58).

The fifth sub-memory cell array SMA5 corresponds to a sub-memory cell array disposed on the outermost side from among a plurality of sub-memory cell arrays included in the data storage structure DSS. The area of the fifth sub-memory cell array SMA5 may be half the area of the fourth sub-memory cell array SMA4. The number of memory cells disposed at one word line of the fifth sub-memory cell array SMA5 may correspond to half of the number of memory cells disposed at one word line of the fourth sub-memory cell array SMA4. The number of bit lines disposed in the fifth sub-memory cell array SMA5 may be half the number of bit lines disposed in the fourth sub-memory cell array SMA4.

Opposite ends of each of the word lines WL41 to WL48 included in the fourth sub-memory cell array SMA4 may be connected to each of metal contacts MC71, MC72, . . . , MC78 and each of metal contacts MC81, MC82, . . . , MC88.

Opposite ends of the word line WL51 included in the fifth sub-memory cell array SMA5 may be respectively connected to the metal contact MC81 and a metal contact MC91. Opposite ends of the word line WL53 may be respectively connected to the metal contact MC83 and a metal contact MC93. Opposite ends of the word line WL55 may be respectively connected to the metal contact MC85 and a metal contact MC95, and opposite ends of the word line WL57 may be respectively connected to the metal contact MC87 and a metal contact MC97.

An even-numbered sub-word line driver block and an odd-numbered sub-word line driver block may be disposed under the fourth sub-memory cell array SMA4.

An even-numbered sub-word line driver block and an odd-numbered sub-word line driver block may be disposed under the fifth sub-memory cell array SMA5. The word line driving voltage output from a sub-word line driver included in the odd-numbered sub-word line driver block may be transferred to the memory cell array structure MAS through the odd-numbered sub-word line driver metal pad OSWD_MP. The odd-numbered sub-word line driver block may apply the word line driving voltages to the opposite ends of the word line WL51 through the metal contact MC81 and the metal contact MC91.

FIG. 12 shows an example of one outermost side of the memory cell array, and the other outermost side facing away from the one outermost side may be similar to the example shown in FIG. 12. However, an even-numbered sub-word line driver block may be disposed under a sub-memory cell array on the other outermost side. The even-numbered sub-word line driver block may apply the word line driving voltages to opposite ends of each of even-numbered word lines among word lines included in the sub-memory cell array on the other outermost side.

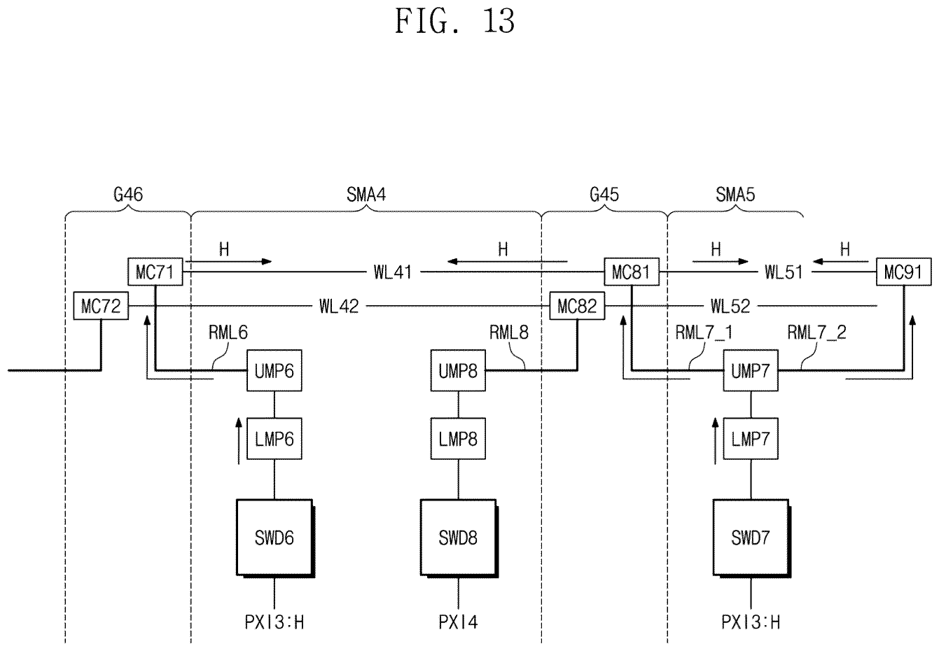

FIG. 13 is a diagram illustrating another example of a word line and a sub-word line driver according to an embodiment of the present disclosure. Referring to FIG. 13, a seventh sub-word line driver SWD7 may apply the word line driving voltages to opposite ends of the word line WL51.

The fifth sub-memory cell array SMA5 may correspond to a sub-memory cell array disposed on the outermost side from among a plurality of sub-memory cell arrays.

The seventh sub-word line driver SWD7 may be disposed under the fifth sub-memory cell array SMA5. The seventh sub-word line driver SWD7 may output the word line driving voltages based on a word line control signal PXI3. The output word line driving voltages may be respectively transferred to the metal contact MC81 and the metal contact MC91 through a lower metal pad LMP7, an upper metal pad UMP7, a routing metal line RML7_1 and a routing metal line RML7_2. The output word line driving voltages may be respectively applied to the opposite ends of the word line WL51 through the metal contact MC81 and the metal contact MC91.

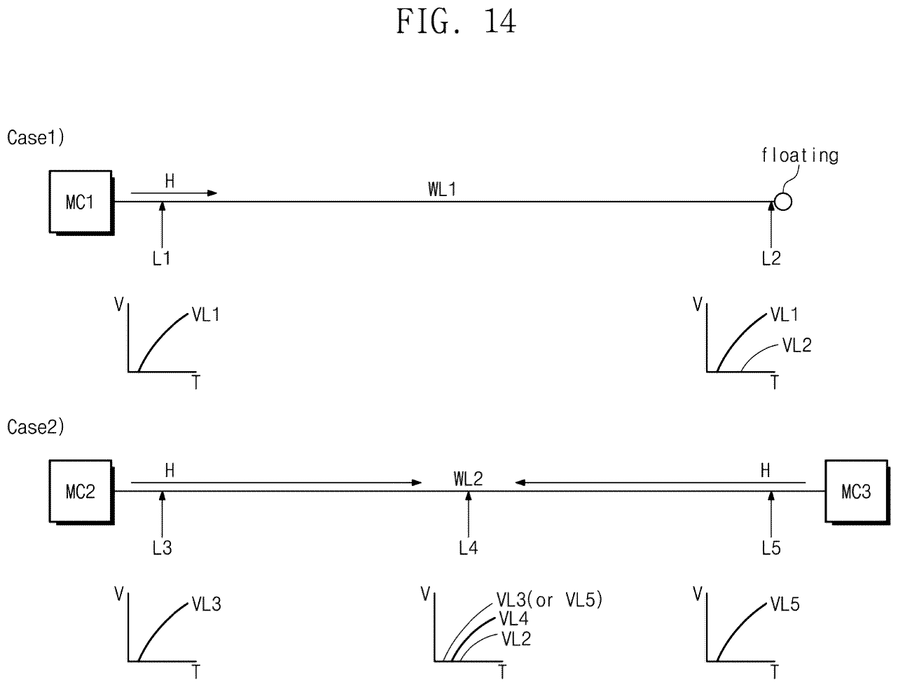

FIG. 14 is a diagram illustrating a slope of a driving voltage for each location, according to an embodiment of the present disclosure. As shown in FIG. 14, the slope of the word line driving voltage may be improved.

Case 1 indicates a case in which the word line driving voltage having the high logic level “H” is only applied to one end of a word line in a semiconductor memory device. For example, a first end of a word line WL1 may be connected to a metal contact MC1, and a second end thereof may be floated. In the structure corresponding to Case 1, when the voltage having the high logic level “H” is applied to the metal contact MC1 at the time of driving the word line WL1, a voltage VL1 of a location L1 of the word line WL1, which is close to the metal contact MC1, may have a relatively good slope. In this case, a voltage VL2 of a location L2 corresponding to the opposite end floated may have the worst slope. Because the semiconductor memory device may operate based on the worst timing to guarantee the integrity of data, the performance of the semiconductor memory device may be relatively low.

Case 2 indicates a case in which the word line driving voltages having the high logic level “H” may be respectively applied to opposite ends of a word line WL2 in the semiconductor memory device 100 according to an embodiment of the present disclosure. For example, a first end of the word line WL2 may be connected to a metal contact MC2, and an opposite end thereof is connected to a metal contact MC3. In the structure corresponding to Case 2, voltages VL3 and VL5 of locations L3 and L5 close to the metal contact MC2 and the metal contact MC3 may have a relatively good slope, and a voltage VL4 of a central location L4 of the word line WL2 may correspond to a location having the worst slope from among locations on the word line WL2. The worst slope of the voltage VL4 of Case 2 may be improved more than the slope of the voltage VL2 on the floated second end of Case 1. In addition, the worst slope of the voltage VL4 of Case 2 may be improved more than a slope of a central portion of the word line WL1 of Case 1. Accordingly, because the timing associated with word line driving may be improved, the performance of operation of the semiconductor memory device 100 of Case 2 may be improved more than the performance of operation of the semiconductor memory device with the structure of Case 1.

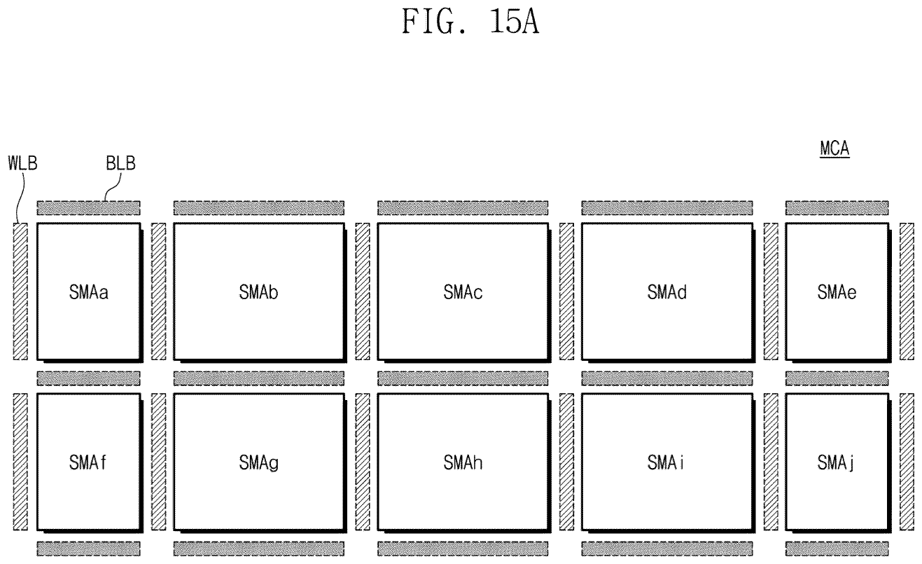

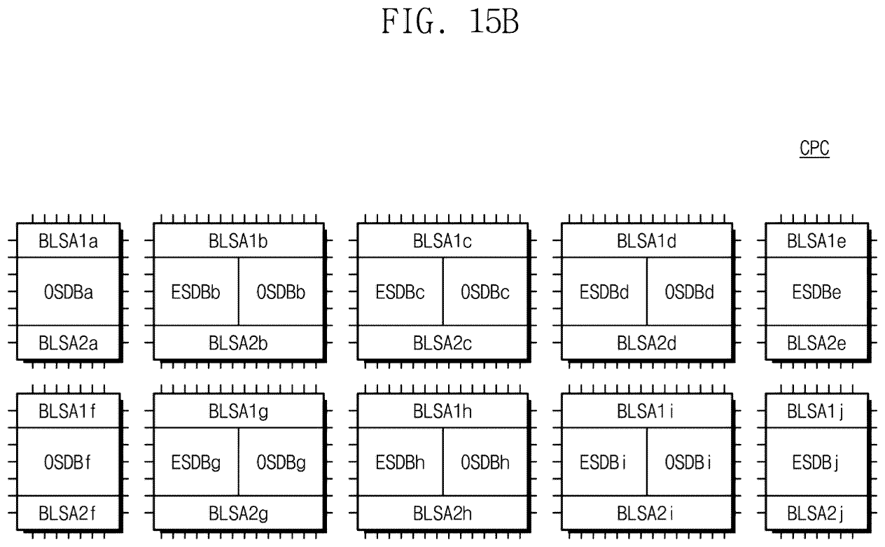

FIG. 15A is a diagram illustrating placement of sub-memory cell arrays of a semiconductor memory device according to an embodiment of the present disclosure, and FIG. 15B is a diagram illustrating placement of core-peripheral circuits corresponding to sub-memory cell arrays of FIG. 15A. Referring to FIG. 15A, the memory cell array MCA may include a sub-memory cell arrays SMAa, SMAb, . . . , SMAj. Each of the sub-memory cell arrays SMAa, SMAb, . . . , SMAj may include a plurality of word lines, a plurality of bit lines, and a plurality of memory cells.

The sub-memory cell arrays SMAa to SMAe may be disposed at the first row, and the sub-memory cell arrays SMAf to SMAj may be disposed at the second row. The sub-memory cell array SMAa may be a sub-memory cell array disposed at a first side end of the first row, and the sub-memory cell array SAMe may be a sub-memory cell array disposed at a second side end of the first row. The sub-memory cell array SMAf may be a sub-memory cell array disposed at a first side end of the second row, and the sub-memory cell array SMAj may be a sub-memory cell array disposed at a second side end of the second row. Word line connection areas WLB or bit line connection areas BLB may be disposed in gap regions or outer regions of the sub-memory cell arrays SMAa, SMAb, . . . , SMAj. The word line connection areas WLB may be disposed in gaps between sub-memory cell arrays of the same row or may be disposed outside sub-memory cell arrays of the same row. The bit line connection areas BLB may be disposed in gaps between sub-memory cell arrays of the same column or may be disposed outside sub-memory cell arrays of the same column. Metal contacts transferring signals to word lines included in sub-memory cell arrays may be formed in the word line connection areas WLB. Metal contacts transferring signals to bit lines included in sub-memory cell arrays may be formed in the bit line connection areas BLB.

Referring to FIG. 15B, the core-peripheral circuit CPC may include a plurality of peripheral circuits respectively corresponding to the sub-memory cell arrays SMAa, SMAb, . . . , SMAj. For example, the core-peripheral circuit CPC may include a first bit line sense amplifier circuit BLSA1a, a second bit line sense amplifier circuit BLSA2a, and an odd-numbered sub-word line driver block OSDBa corresponding to the sub-memory cell array SMAa. The first bit line sense amplifier circuit BLSA1a may be connected to some bit lines included in the sub-memory cell array SMAa, and the second bit line sense amplifier circuit BLSA2a may be connected to other bit lines included in the sub-memory cell array SMAa. The first bit line sense amplifier circuit BLSA1a and the second bit line sense amplifier circuit BLSA2a may control the bit lines of the sub-memory cell array SMAa and may sense and amplify voltage levels of the bit lines. The odd-numbered sub-word line driver block OSDBa may include a plurality of sub-word line drivers. The sub-word line drivers included in the odd-numbered sub-word line driver block OSDBa may drive odd-numbered word lines of the sub-memory cell array SMAa and the sub-memory cell array SMAb.

In addition, the core-peripheral circuit CPC may further include a first bit line sense amplifier circuit BLSA1b, a second bit line sense amplifier circuit BLSA2b, an odd-numbered sub-word line driver block OSDBb, and an even-numbered sub-word line driver block ESDBb corresponding to the sub-memory cell array SMAb. The first bit line sense amplifier circuit BLSA1b and the second bit line sense amplifier circuit BLSA2b may control the bit lines of the sub-memory cell array SMAb and may sense and amplify voltage levels of the bit lines. The even-numbered sub-word line driver block ESDBb may include a plurality of sub-word line drivers. The sub-word line drivers included in the even-numbered sub-word line driver block ESDBb may drive even-numbered word lines of the sub-memory cell array SMAa and the sub-memory cell array SMAb. The odd-numbered sub-word line driver block OSDBb may include a plurality of sub-word line drivers. The sub-word line drivers included in the odd-numbered sub-word line driver block OSDBb may drive odd-numbered word lines of the sub-memory cell array SMAb and the sub-memory cell array SMAc.

Similarly, the core-peripheral circuit CPC may further include first bit line sense amplifier circuits BLSA1c to BLSA1j, second bit line sense amplifier circuits BLSA2c to BLSA2j, odd-numbered sub-word line driver blocks OSDBc to OSDBi, even-numbered sub-word line driver blocks ESDBc to ESDBj.

The sub-memory cell arrays SMAa to SMAj and the peripheral circuits of FIGS. 15A and 15B may be in the shape of a matrix with two rows and five columns, but this is only an example, and embodiments are not limited thereto. The number of rows of sub-memory cell arrays included in the memory cell array MCA may increase or decrease. Also, the number of columns of sub-memory cell arrays may increase or decrease.

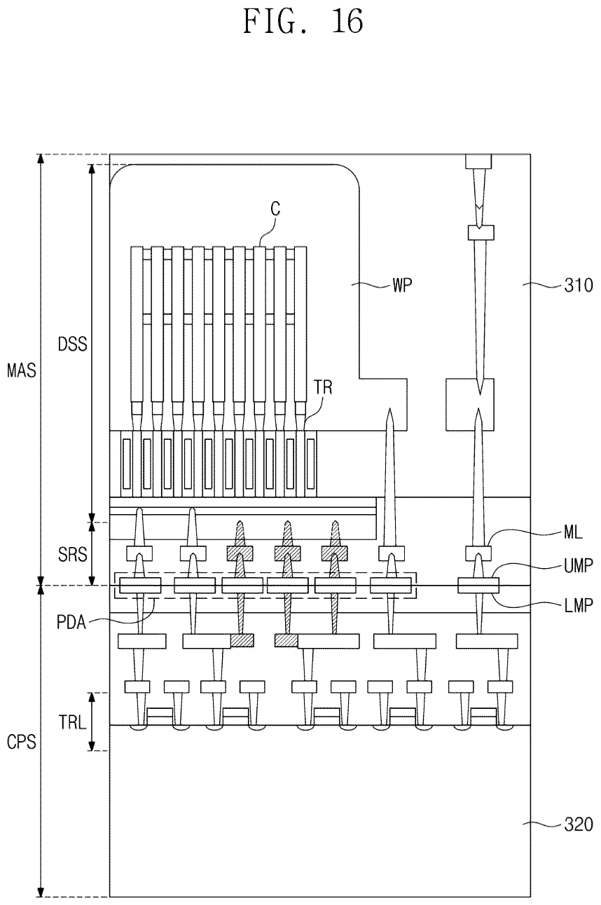

FIG. 16 is a diagram describing an integrated circuit device. Referring to FIG. 16, an integrated circuit device may include the memory cell array structure MAS and the core-peripheral circuit structure CPS.

The memory cell array structure MAS may be formed on the first substrate 310. The memory cell array structure MAS may include the data storage structure DSS and the signal routing structure SRS. The data storage structure DSS may include a plurality of memory cells each including a storage capacitor C and a selection transistor TR, a plurality of bit lines, and a plurality of word lines. The signal routing structure SRS may include a plurality of upper metal pads UMP and a plurality of metal lines ML. The plurality of metal lines ML may provide the electrical connection of the plurality of upper metal pads UMP and components of the data storage structure DSS. For example, the plurality of metal lines ML may provide the electrical connection of some of the plurality of upper metal pads UMP and the bit lines or the electrical connection of some of the plurality of upper metal pads UMP and the word lines.

The core-peripheral circuit structure CPS may be formed on the second substrate 320. The core-peripheral circuit structure CPS may include a transistor layer TRL. A plurality of transistors for driving the memory cell array structure MAS may be disposed on the transistor layer TRL. Some transistors of the plurality of transistors disposed in the transistor layer TRL may be included in bit line sense amplifiers. Other transistors of the plurality of transistors disposed in the transistor layer TRL may be included in a sub-word line driver. The other transistors disposed in the transistor layer TRL may be included in any other peripheral circuit for the operation of the integrated circuit device.

The plurality of upper metal pads UMP and a plurality of lower metal pads LMP may be disposed at locations corresponding to each other and provide the electrical connection between components formed in the first substrate 310 and components formed in the second substrate 320. The plurality of upper metal pads UMP and the plurality of lower metal pads LMP may constitute a pad array PDA.

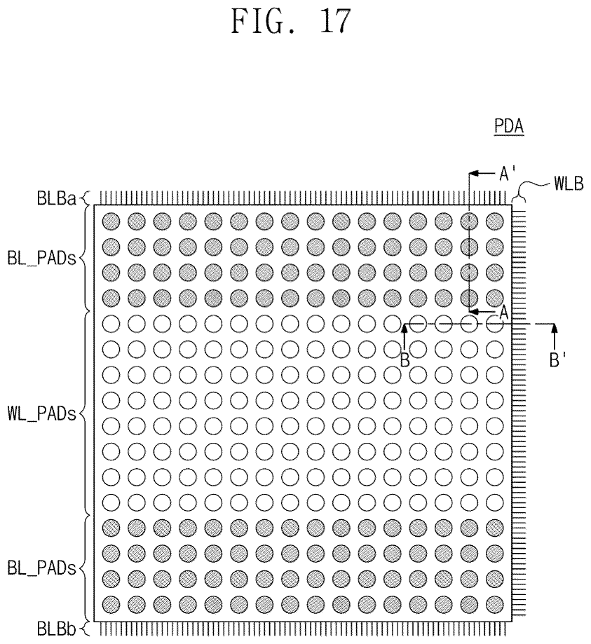

FIG. 17 is a plan view illustrating the pad array PDA of an integrated circuit device of FIG. 16. Referring to FIG. 17, the pad array PDA may include a plurality of bit line pads BL_PADs and a plurality of word line pads WL_PADs. The pad array PDA may correspond to the plurality of upper metal pads UMP illustrated in FIG. 16. The lower metal pads LMP1 may be disposed similarly to the upper metal pads UMP.

The plurality of bit line pads BL_PADs may be disposed in a first peripheral region of a plane and a second peripheral region of the plane, which facing away from the first peripheral region. The plurality of bit line pads BL_PADs may be electrically connected to the bit line connection regions BLB through one or more metal layers. Signals received through the plurality of bit line pads BL_PADs disposed in the first peripheral region may be routed to a bit line connection area BLBa outside the first peripheral region, and signals received through the plurality of bit line pads BL_PADs disposed in the second peripheral region may be routed to a bit line connection area BLBb outside the second peripheral region.

The plurality of word line pads WL_PADs may be electrically connected to the word line connection area WLB through one or more metal layers. Signals received through the plurality of word line pads WL_PADs may be routed to the word line connection area WLB.

The bit line connection areas BLBa and BLBb may provide the electrical connection of the plurality of bit line pads BL_PADs and the bit lines included in the memory cell array. The word line connection area WLB may provide the electrical connection of the plurality of word line pads WL_PADs and the word lines included in the memory cell array.

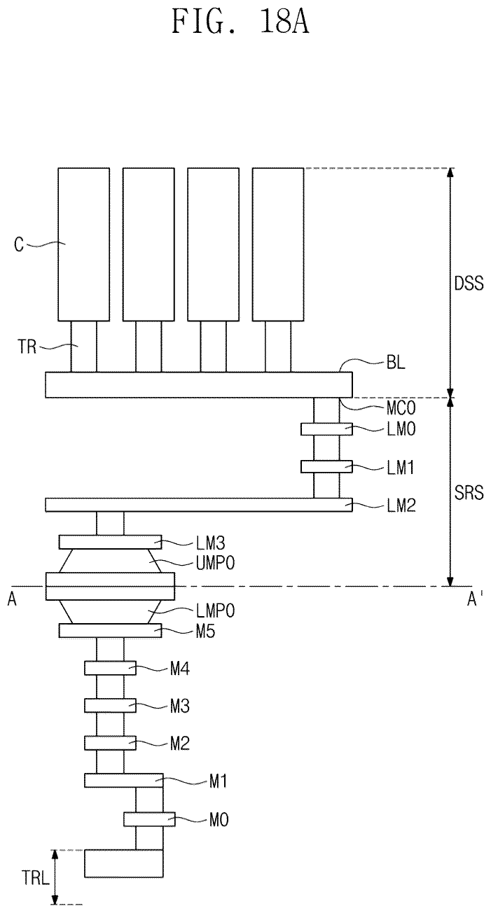

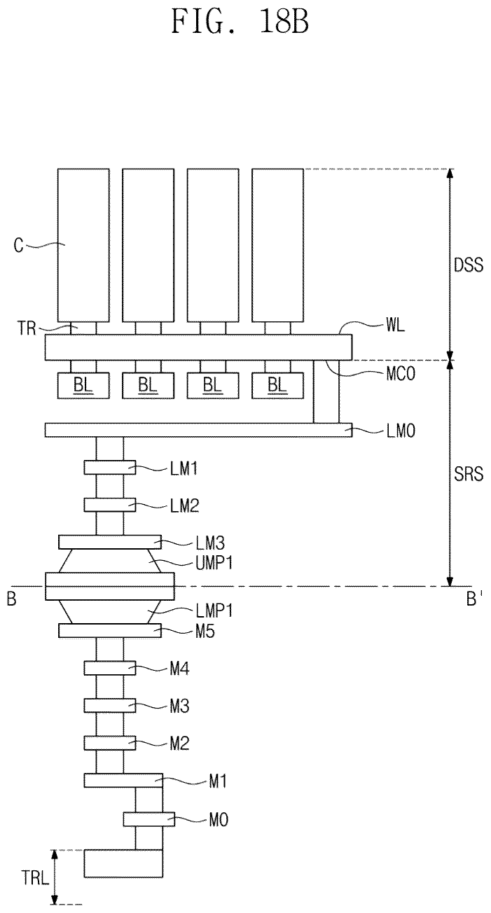

FIG. 18A is a diagram illustrating a vertical cross section of an integrated circuit device taken along line A-A′ of FIG. 17. Referring to FIG. 18A, a bit line sense amplifier circuit disposed in the transistor layer TRL may be electrically connected to the bit line BL.

Remaining components (e.g., neighboring metal pads) other than components providing the electrical connection between the bit line sense amplifier circuit disposed in the transistor layer TRL and the bit line BL may be omitted. The bit line sense amplifier circuit disposed in the transistor layer TRL may be electrically connected to the lower metal pad LMP0 through metal lines M0, M1, M2, M3, M4, and M5. The lower metal pad LMP0 may physically electrically contact the upper metal pad UMP0. The upper metal pad UMP0 may be electrically connected to the plurality of metal lines LM3, LM2, LM1, and LM0. The metal line LM0 may be connected to the bit line BL through a metal contact MC0. The metal contact MC0 may be formed in the bit line connection area BLBa of FIG. 15. The change in a potential of the bit line BL by the storage capacitor C and the selection transistor TR may be applied (or transferred) to the transistor layer TRL through the plurality of metal lines LM0 to LM3, the upper metal pad UMP0, the lower metal pad LMP0, and the plurality of metal lines M0 to M5. The bit line sense amplifier disposed in the transistor layer TRL may sense data stored in the storage capacitor C by amplifying the change in the potential of the bit line BL. The data storage structure DSS may include a plurality of capacitors C, a plurality of selection transistors TR, and a plurality of bit lines BL. The signal routing structure SRS may include the plurality of metal lines LM0 to LM3 and the upper metal pad UMP0.

FIG. 18B is a diagram illustrating a vertical cross section of an integrated circuit device taken along line B-B′ of FIG. 17. Referring to FIG. 18B, a sub-word line driver disposed in the transistor layer TRL may be electrically connected to the word line WL.

Remaining components (e.g., neighboring metal pads) other than components providing the electrical connection between the sub-word line driver disposed in the transistor layer TRL and the word line WL may be omitted. The sub-word line driver disposed in the transistor layer TRL may be electrically connected to the lower metal pad LMP1 through the metal lines M0, M1, M2, M3, M4, and M5. The lower metal pad LMP1 may physically and electrically contact the upper metal pad UMP1. The upper metal pad UMP1 may be electrically connected to the plurality of metal lines LM3, LM2, LM1, and LM0. The metal line LM0 may be connected to the word line WL through the metal contact MC0. The metal contact MC0 may be formed in the word line connection area WLB of FIG. 15. A word line driving voltage which the sub-word line driver outputs may be applied to the word line WL through the plurality of metal lines M0 to M5, the lower metal pad LMP1, the upper metal pad UMP1, the plurality of metal lines LM0 to LM3, and the metal contact MC0. The selection transistor TR may be switched by the word line driving voltage applied to the word line WL, and thus, the bit line BL and the storage capacitor C may be connected. The data storage structure DSS may include the plurality of storage capacitors C, the plurality of the selection transistors TR, the plurality of bit lines BL, and the plurality of word lines WL. The signal routing structure SRS may include the plurality of metal lines LM0 to LM3 and the upper metal pad UMP1.

As described above, a semiconductor memory device according to embodiments of the present disclosure may have a structure in which opposite ends of a word line may be connected to sub-word line drivers. According to the above structure, operating voltages may be applied to the opposite ends of the word line. Accordingly, the slope of a driving voltage applied to a sub-word line may be improved, and the performance of the semiconductor memory device may be improved.

A semiconductor memory device according to an embodiment of the present disclosure may have a structure in which opposite ends of a word line may be respectively connected to sub-word line drivers. According to the above structure, operating voltages may be applied to the opposite ends of the word line. Accordingly, the slope of a driving voltage applied to a sub-word line may be improved, and the performance of the semiconductor memory device may be improved.

While some embodiments of the present disclosure are described above, it will be apparent to those of ordinary skill in the art that various changes and modifications may be made thereto without departing from the spirit and scope of the present disclosure as set forth in the following claims.

What is claimed is:

1. A semiconductor memory device comprising:
a first semiconductor structure comprising a first sub-memory cell array which comprises a first plurality of word lines, a plurality of bit lines, and a plurality of memory cells, and a plurality of upper metal pads electrically connected to the first plurality of word lines and the plurality of bit lines; and
a second semiconductor structure disposed under the first semiconductor structure, and comprising a plurality of sub-word line drivers,
wherein the plurality of sub-word line drivers comprise:
a first sub-word line driver configured to supply a word line driving voltage to a first end of a first word line from among the first plurality of word lines,
a second sub-word line driver configured to supply the word line driving voltage to a second end of the first word line,
a third sub-word line driver configured to supply the word line driving voltage to a first end of a second word line from among the first plurality of word lines,
a fourth sub-word line driver configured to supply the word line driving voltage to a second end of the second word line, and
a plurality of lower metal pads electrically connected to the plurality of sub-word line drivers, and
wherein each upper metal pad from among the plurality of upper metal pads is bonded to a corresponding lower metal pad from among the plurality of lower metal pads in a one-to-one correspondence.

2. The semiconductor memory device of claim 1, wherein each of the first sub-word line driver to the fourth sub-word line driver comprises a first transistor, a second transistor, and a third transistor,
wherein a gate terminal of the first transistor is configured to receive a word line enable signal, a source terminal of the first transistor is configured to receive a corresponding word line driving signal, and a drain terminal of the first transistor is electrically connected to a word line from among the first plurality of word lines,
wherein a gate terminal of the second transistor is configured to receive the word line enable signal, a drain terminal of the second transistor is connected to the drain terminal of the first transistor, and a source terminal of the second transistor is connected to a ground, and
wherein a gate terminal of the third transistor is configured to receive a corresponding inverted word line driving signal, a drain terminal of the third transistor is connected to the drain terminal of the first transistor, and a source terminal of the third transistor is connected to the ground.

3. The semiconductor memory device of claim 1, wherein the first sub-word line driver and the fourth sub-word line driver are in a region under the first sub-memory cell array.

4. The semiconductor memory device of claim 3, wherein the first semiconductor structure further comprises:
a second sub-memory cell array adjacent to a first side of the first sub-memory cell array; and
a third sub-memory cell array adjacent to a second side of the first sub-memory cell array, which faces away from the second sub-memory cell array,
wherein the second sub-word line driver is in a region under the second sub-memory cell array, and
wherein the third sub-word line driver is in a region under the third sub-memory cell array.

5. The semiconductor memory device of claim 4, wherein the third sub-word line driver is configured to supply the word line driving voltage to a first end of a first word line from among a third plurality of word lines disposed in the third sub-memory cell array, and
wherein the fourth sub-word line driver is configured to supply the word line driving voltage to a first end of a second word line from among a second plurality of word lines disposed in the second sub-memory cell array.

6. The semiconductor memory device of claim 3, wherein the second semiconductor structure further comprises:
a first bit line sense amplifier circuit connected to some bit lines from among the plurality of bit lines; and
a second bit line sense amplifier circuit connected to other bit lines from among the plurality of bit lines.

7. The semiconductor memory device of claim 6, wherein the first bit line sense amplifier circuit is in a first outermost region included in the region under the first sub-memory cell array,
wherein the second bit line sense amplifier circuit is in a second outermost region included in the region under the first sub-memory cell array, and
wherein the second outermost region faces away from the first outermost region.

8. The semiconductor memory device of claim 7, wherein the first sub-word line driver and the fourth sub-word line driver are in a region which is between the first outermost region and the second outermost region, and is included in the region under the first sub-memory cell array.

9. The semiconductor memory device of claim 1, wherein the first word line is an odd-numbered word line from among the first plurality of word lines, and the second word line is an even-numbered word line from among the first plurality of word lines.

10. A semiconductor memory device comprising:
a memory cell array structure on a first substrate and comprising a plurality of sub-memory cell arrays which comprise a plurality of word lines, a plurality of bit lines, and a plurality of memory cells;
a core-peripheral circuit structure on a second substrate under the first substrate, wherein the core-peripheral circuit structure comprises:
a first sub-word line driver block configured to supply a word line driving voltage to first ends of first odd-numbered word lines from among a first plurality of word lines in a first sub-memory cell array from among the plurality of sub-memory cell arrays,
a second sub-word line driver block configured to supply the word line driving voltage to second ends of the first odd-numbered word lines,
a third sub-word line driver block configured to supply the word line driving voltage to first ends of first even-numbered word lines from among the first plurality of word lines, and
a fourth sub-word line driver block configured to supply the word line driving voltage to second ends of the first even-numbered word lines; and
a plurality of metal pad junctions electrically connecting the memory cell array structure with the core-peripheral circuit structure.

11. The semiconductor memory device of claim 10, wherein the first sub-word line driver block and the fourth sub-word line driver block are in a region under the first sub-memory cell array.

12. The semiconductor memory device of claim 11, wherein the second sub-word line driver block is in a region under a second sub-memory cell array which is adjacent to the first sub-memory cell array from among the plurality of sub-memory cell arrays in a direction toward the first plurality of word lines, and
wherein the third sub-word line driver block is in a region under a third sub-memory cell array which faces away from the second sub-memory cell array and is adjacent to the first sub-memory cell array from among the plurality of sub-memory cell arrays.

13. The semiconductor memory device of claim 12, wherein the first sub-word line driver block is further configured to supply the word line driving voltage to first ends of third odd-numbered word lines from among a third plurality of word lines in the third sub-memory cell array,
wherein the second sub-word line driver block is further configured to supply the word line driving voltage to a first ends of second odd-numbered word lines from among a second plurality of word lines in the second sub-memory cell array,
wherein the third sub-word line driver block is further configured to supply the word line driving voltage to first ends of third even-numbered word lines from among the third plurality of word lines, and
wherein the fourth sub-word line driver block is further configured to supply the word line driving voltage to first ends of second even-numbered word lines from among the second plurality of word lines.

14. The semiconductor memory device of claim 10, wherein the first odd-numbered word lines are arranged alternatingly with the first even-numbered word lines.

15. The semiconductor memory device of claim 11, wherein the core-peripheral circuit structure further comprises:
a first bit line sense amplifier circuit electrically connected to first bit lines among a plurality of bit lines in the first sub-memory cell array; and
a second bit line sense amplifier circuit electrically connected to second bit lines among the plurality of bit lines in the first sub-memory cell array,
wherein the first bit line sense amplifier circuit is in a first outermost region included in the region under the first sub-memory cell array, and
wherein the second bit line sense amplifier circuit is in a second outermost region included in the region under the first sub-memory cell array, and
wherein the second outermost region faces away from the first outermost region.

16. The semiconductor memory device of claim 15, wherein the first sub-word line driver block and the second sub-word line driver block are between the first outermost region and the second outermost region.

17. A semiconductor memory device comprising:
a first substrate;
a first sub-memory cell array on the first substrate and comprising a first plurality of word lines;
a plurality of upper metal pads in a matrix array shape on the first sub-memory cell array;
one or more first metal layers electrically connecting the plurality of upper metal pads with opposite ends of each word line of the first plurality of word lines;
a second substrate on a lower side of the first substrate;
a transistor layer on the second substrate and comprising a plurality of sub-word line drivers;
a plurality of lower metal pads in the matrix array shape on an upper side of the transistor layer, wherein each lower metal pad from among the plurality of lower metal pads is bonded to a corresponding upper metal pad from among the plurality of upper metal pads; and
one or more second metal layers electrically connecting the plurality of lower metal pads with the transistor layer,
wherein each first sub-word line driver from among a plurality first sub-word line drivers included in the plurality of sub-word line drivers is electrically connected to a first metal contact formed at a first end of a corresponding odd-numbered word line from among a plurality of odd-numbered word lines included in the first plurality of word lines,
wherein each second sub-word line driver from among a plurality of second sub-word line drivers included in the plurality of sub-word line drivers is electrically connected to a second metal contact formed at a second end of the corresponding odd-numbered word line,
wherein each third sub-word line driver from among a plurality of third sub-word line drivers included in the plurality of sub-word line drivers is electrically connected to a third metal contact formed at a first end of a corresponding even-numbered word line word line from among a plurality of even-numbered word lines included in the first plurality of word lines, and
wherein each fourth sub-word line driver from among a plurality of fourth sub-word line drivers included in the plurality of sub-word line drivers is electrically connected to a fourth metal contact formed at a second end of the corresponding even-numbered word line.

18. The semiconductor memory device of claim 17, further comprising:
a second sub-memory cell array adjacent to a first side of the first sub-memory cell array; and
a third sub-memory cell array adjacent to opposite second side of the first sub-memory cell array which faces away from the second sub-memory cell array,
wherein the plurality of first sub-word line drivers and the plurality of fourth sub-word line drivers are in a region under the first sub-memory cell array,
wherein the plurality of second sub-word line drivers are in a region under the second sub-memory cell array, and
wherein the plurality of third sub-word line drivers are in a region under the third sub-memory cell array.

19. The semiconductor memory device of claim 18, wherein second odd-numbered word lines from among a second plurality of word lines included in the second sub-memory cell array are electrically connected to the plurality of second sub-word line drivers through the second metal contact,
wherein second even-numbered word lines from among the second plurality of word lines are electrically connected to the plurality of fourth sub-word line drivers through the fourth metal contact,
wherein third odd-numbered word lines from among a third plurality of word lines included in the third sub-memory cell array are electrically connected to the first plurality of sub-word line drivers through the first metal contact, and
wherein third even-numbered word lines from among the third plurality of word lines are electrically connected to the plurality of third sub-word line drivers through the third metal contact.

20. The semiconductor memory device of claim 19, wherein the first metal contact and the third metal contact are in a first connection area between the first sub-memory cell array and the third sub-memory cell array, and
wherein the second metal contact and the fourth metal contact are in a second connection area between the first sub-memory cell array and the second sub-memory cell array.
